(19) United States
(12) Patent Application Publication
(10) Pub. No.: US 2025/0232805 A1
(43) Pub. Date: Jul. 17, 2025

(54) MEMORY CIRCUITS WITH TRACKING CELLS AND METHODS FOR OPERATING THE SAME

(71) Applicant: Taiwan Semiconductor Manufacturing Company, Ltd., Hsinchu (TW)

(72) Inventors: Yumito Aoyagi, Hsinchu City (TW); Makoto Yabuuchi, Hsinchu City (TW); Hiromasa Otsubo, Hsinchu City (TW)

(73) Assignee: Taiwan Semiconductor Manufacturing Company, Ltd., Hsinchu (TW)

(21) Appl. No.: 18/630,365

(22) Filed: Apr. 9, 2024

Related U.S. Application Data
(60) Provisional application No. 63/620,799, filed on Jan. 13, 2024.

(51) Int. Cl. G11C 11/419

(52) U.S. Cl. CPC G11C 11/419

(57) ABSTRACT

A circuit includes a memory array comprising a plurality of first memory cells. The memory circuit includes a tracking column comprising one or more second memory cells, wherein each of the one or more second memory cells is coupled to a first tracking bit line, a second tracking bit line, and a first tracking word line. The memory circuit includes a controller operatively coupled to the memory array and the tracking column, and configured to: identify a transition edge of a first signal present on the first tracking bit line and assert a second signal present on the first tracking word line, causing a third signal present on the second tracking bit line to rise; and generate a trigger signal based on the third signal, wherein a transition edge of the trigger signal causes a write operation performed on at least one of the first memory cells to cease.

### CROSS-REFERENCE TO RELATED APPLICATION

This application claims priority to and the benefit of U.S. Provisional Application No. 63/620,799, filed Jan. 13, 2024, entitled “Write Weak-Bit Tracking Circuit With Write Tracking Cell,” which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device including a memory controller, in accordance with some embodiments.

FIGS. 2, 3, 4, 5, 6, 7, 8, and 9 illustrate implementations of the memory controller of FIG. 1, respectively, in accordance with some embodiments.

FIG. 10 illustrates waveforms of various signals to operate at least one of the memory controllers of FIGS. 2-9, in accordance with some embodiments.

FIG. 11 illustrates an example circuit diagram of a tracking cell, in accordance with some embodiments.

FIG. 12 illustrates waveforms of various signals to operate at least one of the memory controllers of FIGS. 2-9, in accordance with some embodiments.

FIG. 13 illustrates another example circuit diagram of a tracking cell, in accordance with some embodiments.

FIG. 14 illustrates an example layout configured to form the tracking cell of FIG. 13, in accordance with some embodiments.

FIG. 15 illustrates yet another example circuit diagram of a tracking cell, in accordance with some embodiments.

FIG. 16 illustrates an example layout configured to form the tracking cell of FIG. 15, in accordance with some embodiments.

FIG. 17 illustrates yet another example circuit diagram of a tracking cell, in accordance with some embodiments.

FIG. 18 illustrates an example layout configured to form the tracking cell of FIG. 17, in accordance with some embodiments.

FIG. 19 illustrates an example circuit diagram of an adjustment circuit coupled to a tracking bit line, in accordance with some embodiments.

FIG. 20 illustrates a graph comparing performances of various memory devices, in accordance with some embodiments.

FIG. 21 illustrates an example flow chart of a method for operating a memory device including a memory controller configured to adjust the timing of a falling edge of an internal clock signal, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A static random access memory (SRAM) device is a type of volatile semiconductor memory that stores data bits using bistable circuitry that does not need refreshing. An SRAM cell may be referred to as a bit cell because it stores one bit of information, represented by the logic state of two cross coupled inverters. Memory arrays include multiple bit cells arranged in rows and columns. Each bit cell in a memory array typically includes connections to a power supply voltage and to a reference voltage. Logic signals on bit lines control reading from and writing to a bit cell, with a word line controlling connections of the bit lines to the inverters. A word line may be coupled to the bit cells in a row of a memory array, with different word lines provided for different rows.

Each successive bit cell along a bit line or word line has a characteristic input capacitance, and each conductor leg (e.g., a part of bit line or word line) between bit cells has a resistance, leading to a signal propagation delay. The delay is longer for bit cells that are farther than others along signal paths beginning at the source of memory addressing and control signals, such as the outputs of address decoding gates and line drivers coupled at an edge of the memory array. The delay affects the time needed to access the bit cells and limits the highest frequency at which the memory can be operated. The time taken to access an SRAM bit cell, e.g., for a read/write operation, may vary due to several factors including the relative position of the accessed bit cell within the SRAM array. Reliable estimation of SRAM timing characteristics is important for ensuring consistency in system components and high system performance.

In this regard, various techniques have been proposed to provide timing tracking functionality for accurate, efficient monitoring of an SRAM device. Timing tracking enables determination of when a nominal memory cell finishes a read or write operation. For example, tracking cells, which are substantially similar to the nominal memory cells that store data, are enlisted or repurposed to provide a signal for controlling the timing of memory operations. In general, a tracking cell is connected to a tracking word line and a tracking bit line. The timing with which the tracking cell pulls down a voltage on the tracking bit line triggers a timing signal (sometimes referred to as a “TRIG signal”). The TRIG signal would provide the correct timing to pull down an internal clock signal (e.g., then pull down a word line signal), so as to define the time window of an operation (e.g., a write operation) performed on the nominal memory cell.

Due to manufacturing variations, however, not all the nominal memory cells are equivalent to the tracking cell. To account for these variations, a delay may be added to the TRIG signal. That delay, provided by a delay circuit, may be predetermined. For example, the delay is typically estimated based on how much longer a slow memory cell, e.g., the memory cell formed at the slow Process Voltage Temperature (PVT) corner of an array, may take than an average memory cell to pull down the bit line voltage. A delay made sufficiently large for the slowest PVT corner in terms of process variability commonly adds unnecessary delay to the operations for memory cells at other PVT conditions. These unnecessary delays slow the memory operation significantly. Thus, the existing timing tracking techniques or corresponding circuits for an SRAM device have not been entirely satisfactory in certain aspects.

The present disclosure provides various embodiments of a memory device including a controller, at least one memory array, and a tracking column. In various embodiments, the memory array includes a number of nominal memory cells configured to store data, and the tracking column includes a number of tracking cells configured to provide signals for determination on the tracking timing. For example, at least one of the tracking cells may be coupled to a pair of tracking bit lines and a tracking word line. One of the tracking bit lines (sometimes referred to as “TRKBL”) can be pre-charged to a voltage level corresponding to a logic 1 (e.g., VDD), and the other (sometimes referred to as “TRKBLB”) can be pre-discharged to a voltage level corresponding to a logic 0 (e.g., VSS). The at least one tracking cell can be controlled (e.g., activated or deactivated) by the tracking word line (sometimes referred to “TRKWL”). Such tracking bit lines (TRKBL and TRKBLB) and tracking word line (TRKWL) essentially have the same RC effect as nominal bit lines and word line that are formed within the memory array. As such, the operation timing of a nominal memory cell that is coupled to the corresponding nominal bit lines and word lines, regardless of being formed in a fast or slow corner, can still be accurately tracked, or otherwise captured. In other words, no delay circuit with a pre-estimated delay is needed to provide a timing tracking technique.

In various aspects of the present disclosure, the controller can provide a tracking technique by first pulling up a voltage present on the tracking word line (a TRKWL signal), which closely follows a voltage present on the nominal word line. In some embodiments, the TRKWL signal can be asserted (e.g., pulled up) according to the rising edge of an internal clock (ICLK) signal. In some other embodiments, the TRKWL signal can be asserted (e.g., pulled up) according to the falling edge of a voltage present on the pre-charged tracking bit line (a TRKBL signal). The pulled-up TRKWL signal can activate the tracking cell. Next, the controller can identify a rising edge of the voltage present on the pre-discharged tacking bit line (a TRKBLB signal). In various embodiments, the controller may generate a trigger (TRIG) signal that closely follows the TRKBLB signal. Upon the TRIG signal transitioning to a logic 1 (being asserted or pulled up), the controller can determine to negate (e.g., pull down) the ICLK signal, which causes an operation (e.g., a write operation) performed on the nominal bit cell to be ceased. In this way, the controller, as disclosed herein, do not rely on a delay circuit with a pre-estimated delay to determine when to negate (e.g., pull down) the internal clock signal. Accordingly, power waste, especially on those slower nominal memory cells, can be significantly reduced.

In some other embodiments of the present disclosure, the transition direction of the various signal mentioned above can be reversed by adding an odd number of inverse logic gates (e.g., an inverter) or utilizing an opposite conductive type of transistors. That is, when a signal is asserted, the signal may transition to a logic 0. Similarly, when a signal is negated, the signal may transition to a logic 1. Purely for purposes of clarity, the following discussion will be directed to asserting a signal through pulling up its logic state and negating a signal through pulling down its logic state.

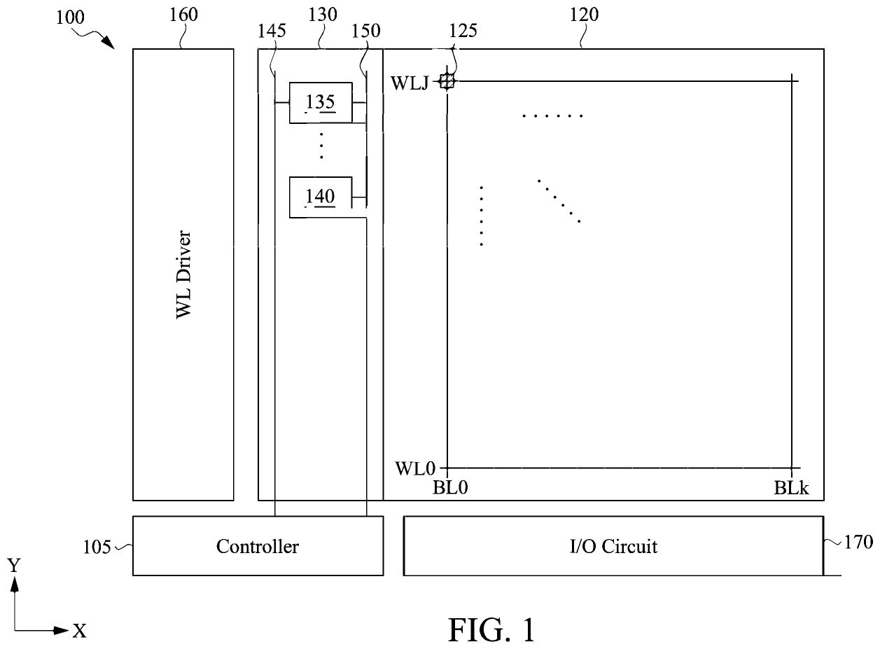

FIG. 1 illustrates a block diagram of a memory device 100, in accordance with various embodiments. The memory device 100 shown in FIG. 1 is simplified for illustration purposes, and thus, it should be appreciated that the memory device 100 can include any of various other components while remaining within the scope of the present disclosure.

As shown, the memory device 100 includes a memory controller 105 and a memory array 120. The memory array 120 may include a plurality of storage circuits or memory cells 125 arranged in two- or three-dimensional arrays. Each memory cell 125 may be coupled to one or more corresponding word lines (WLs) and one or more corresponding bit line (BLs). The memory controller 105 can write data to or read data from the memory array 120 according to electrical signals through word lines WL and bit lines BL. Further, according to various embodiments of the present disclosure, the memory controller 105 can adjust the pulse width of a WL signal conducted through a corresponding asserted word line WL based on the timing of a voltage level discharged through a tracking cell, which will be discussed in further detail below. In other embodiments, the memory device 100 includes more, fewer, or different components than shown in FIG. 1.

The memory array 120 is a hardware component that stores data. In one aspect, the memory array 120 includes a plurality of storage circuits or memory cells 125. The memory array 120 includes word lines WL₀ . . . WL_{J}, each extending in a first direction (e.g., the X-direction) and bit lines BL₀ . . . BL_{K}, each extending in a second direction (e.g., the Y-direction). In some embodiments, the memory array 120 may be referred to as having a number of columns and a number of rows, where each of the columns corresponds to a respective one of the bit lines BLs and each of the rows corresponds to a respective one of the word lines WLs. That is, the memory array 120 can include K columns and J rows of the memory cells 125. The word lines WL and the bit lines BL may be conductive metals or conductive rails. Each memory cell 125 is coupled to a corresponding word line WL and a corresponding bit line BL, and can be operated according to voltages or currents through the corresponding word line WL and the corresponding bit line BL.

In some embodiments, each bit line includes bit lines, BL and BLB, coupled to one or more memory cells 125 of a group of memory cells 125 disposed along the second direction (e.g., the Y-direction). The bit lines, BL and BLB, may receive and/or provide differential signals. Each memory cell 125 may include a volatile memory, a non-volatile memory, or a combination of them. In some embodiments, each memory cell 125 is embodied as a static random access memory (SRAM) cell or other type of memory cell. In some embodiments, the memory array 120 includes additional lines (e.g., select lines, reference lines, reference control lines, power rails, etc.).

For example, the memory cell 125 may be is implemented as a six-transistor (6T) static random access memory (SRAM) cell that consists of six transistors. Generally, the nominal memory cell 125 includes a pair of access or pass-gate transistors, PG1 and PG2, biased by (e.g., gated by) a corresponding word line WL. The pass-gate transistors PG1 and PG2 provide access to cross-coupled first and second inverters, respectively. The pass-gate transistors PG1 and PG2 can pass bit lines signals to internal nodes of the cross-coupled inverters, when the WL signal fed into the gate terminals of the pass-gate transistors PG1 and PG2 becomes true. The first inverter includes a pull-up (e.g., PMOS) transistor PU1 and a pull-down (e.g., NMOS) transistor PD1, and the second inverter includes a pull-up (e.g., PMOS) transistor PU2 and a pull-down (e.g., NMOS) transistor PD2. The pass-gate transistors PG1 and PG2 respectively are coupled to a first bit line BL (“bit line”) and to a second bit line BLB (“bit line bar” or bit line complement). This configuration is referred to as a 6T (six-transistor) configuration.

During a standby mode, the WL is not asserted, and thus the pass-gate transistors PG1 and PG2 disconnect the memory cell 125 from the bit lines, the BL and BLB. The cross-coupled inverters are coupled between power supplies (VDD and VSS), and reinforce each other to maintain one of two possible logic states with a stored data bit at one of the internal nodes between the inverters (sometimes referred to as a node Q or node BL_IN) and the complement of that bit at the other node between the inverters (sometimes referred to as a node QB or node BLB_IN). During a read operation, the BL and BLB are pre-charged to a high logic state (e.g., a logic 1), and the WL is asserted. The stored data bit at the node Q is transferred to the BL, and the data bit at the node QB is transferred to the BLB. During a write operation, the value to be written is provided at the BL, and the complement of that value is provided at the BLB, when the WL is asserted. Although the 6T SRAM cells are herein described as an example implementation of the memory cell 125, it should be understood that the memory cell 125 can be implemented as other types of memory cells, including types of memory other than SRAM and other types of SRAM configurations than 6T (e.g., eight transistor (8T) or ten transistor (10T) configurations) while remaining within the scope of the present disclosure.

In addition to the memory cells 125 configured to store data (which are sometimes referred to as nominal memory cells 125), the memory device 100 may include one or more tracking columns 130 disposed next to or integrated into the memory array 120. For example, in FIG. 1, the tracking column 130 may be disposed along one of the edges of the memory array 120 that extend in parallel with the bit lines, BL₀ to BL_{K}. The tracking column 130 can each include a number of tracking cells 135 and optionally include a number of dummy cells 140. Further, the tracking column 130 may include two types of tracking cells 135, one is configured to track a read operation performed on the nominal memory cells (sometimes referred to as a read tracking cell) and the other of which is configured to track a write operation performed on the nominal memory cells (sometimes referred to as a write tracking cell), in some embodiments. The tracking cells 135 and the dummy cells 140 may be configured in any respective numbers, while remaining within the scope of the present disclosure. In some embodiments, a total number of the tracking cells 135 and dummy cells 140 may be equal to the number of rows (J). For example, the number of tracking cells 135 may be selected to simulate a worst-case condition in a write and/or read operation.

In some embodiments, the tracking column 130 can further include one or more tracking word lines 145, and one or more tracking bit lines 150. In accordance with the different (write and read) types of the tracking cells 135, the tracking column 130 may also include two types of tracking word lines, e.g., a write tracking word line and a read tracking word line. The write tracking cell may be coupled to (or activated by) the write tracking word line, and the read tracking cell may be coupled to (or activated by) the read tracking word line. In general, each of the tracking cells 135 may be operatively coupled to a corresponding tracking word line 145, and operatively coupled to one or more corresponding tracking bit lines 150. However, each of the dummy cells 140 may not be operatively coupled to any tracking word line 145, but operatively coupled tot at least one corresponding tracking bit line 150.

For example, the tracking column 130 may include one tracking word line (TRKWL) operatively coupled to a write tracking cell 135, one tracking bit line (TRKBL) operatively coupled to the write tracking cell 135, and one tracking bit line bar (TRKBLB) operatively coupled to the write tracking cell 135. In another example, the tracking column 130 may include one tracking word line (TRKWL) operatively coupled to a write tracking cell 135 but not coupled to a dummy cell 140, one tracking bit line (TRKBL) operatively coupled to the write tracking cell 135 and also coupled to the dummy cell 140, and one tracking bit line bar (TRKBLB) operatively coupled to the write tracking cell 135 but not coupled to the dummy cell 140. In yet another example, the tracking column 130 may include one write tracking word line (WTRKWL) operatively coupled to a write tracking cell 135, one read tracking word line (RTRKWL) operatively coupled to a read tracking cell 135, one tracking bit line (TRKBL) operatively coupled to both of the write and read tracking cells 135, and one tracking bit line bar (TRKBLB) operatively coupled to the write tracking cell 135 but not to the read tracking cell 135. The tracking word line 145 and tracking bit line 150 are configured to conduct respective tracking signals (e.g., a TRKBL signal, TRKBLB signal, a TRKWL/WTRKWL signal, a RTRKWL signal, etc.), which will be discussed in further detail below. By conducting the tracking signals, the tracking word line 145 and tracking bit line 150 can respectively emulate signal routing delays in a functional memory array (e.g., 120) for a read or write operation at the far edge.

For example, the tracking word line 145 may include a (e.g., horizontal) portion extending along the rows of the memory array 120 (not expressly shown), and the (e.g., vertical) portion shown in FIG. 1 that extends along the columns of the memory array 120. A length of the vertical portion of the tracking word line 145 may be approximately equal to a height of the memory array (e.g., a distance from the memory controller 105 to the farthest tracking cell 135 or dummy cell 140, according to the orientation of the memory array in FIG. 1); and a length of the horizontal portion of the tracking word line 145 may be approximately equal to a width of the memory array 120 (e.g., a distance along any of the rows from one edge of the array to the other, according to the orientation of the memory array in FIG. 1). Accordingly, a sum of the lengths of the first and second portions of the tracking word line 145 may be such that the metal routing delay for accessing a cell at the top right corner of the memory array 120 is emulated, e.g., the delay from signal entry at the bottom left, propagating horizontally and vertically, over a path distance equal to the length of a path from one corner to the diagonally opposite corner.

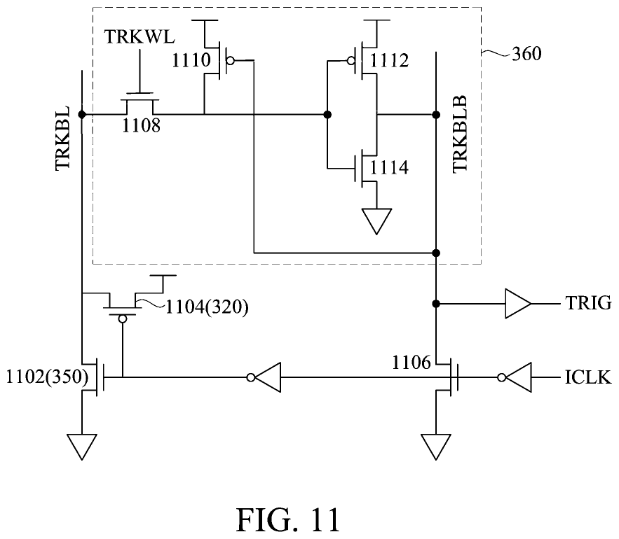

In general, the tracking cells 135 do not function as the (nominal) memory cells 125 do in terms of storing data and supporting read/write operations. Rather, the tracking cells 135 may originally be a subset of the nominal memory cells 125 but be enlisted, or re-purposed, for timing tracking. For example, the tracking cells 135 are bit cells with fixed logic values configured and coupled to one another so as to respond in a predictable way when addressed by test or tracking signals. Some non-limiting implementations of the tracking cell 135 will be discussed below with respect to FIGS. 11-18. The dummy cells 140 enable the capacitive and resistive environment to be matched closely for accurate modeling of the environment for nominal memory cells. Bit lines that are tracked typically have two factors that determine propagation delay of signals that are carried, namely serial resistance and parallel capacitance. The dummy cells 140 have real capacitive load, and mimic the capacitance of bit lines BLs coupled to the nominal memory cells. If the dummy cells 140 were not provided, the length of the tracking bit line would effectively appear to be shorter than the nominal bit lines BLs they are intended to emulate, which would decrease resistance and capacitance, and which might lead tracking circuitry to determine that read or write operations have concluded prematurely.

The memory controller 105 is a hardware component that is configured to control various operations of the memory array 120 such as, reading data bits from the memory cells 125, writing data bits into the memory cells 125, performing a tracking scheme on respective timings of the read/write operation, adjusting the tracking timings of the read/write operation, etc. In various embodiments, the memory controller 105 can include a number of circuits, each of which may be embodied as logic circuits, analog circuits, or a combination of them, to perform such operations.

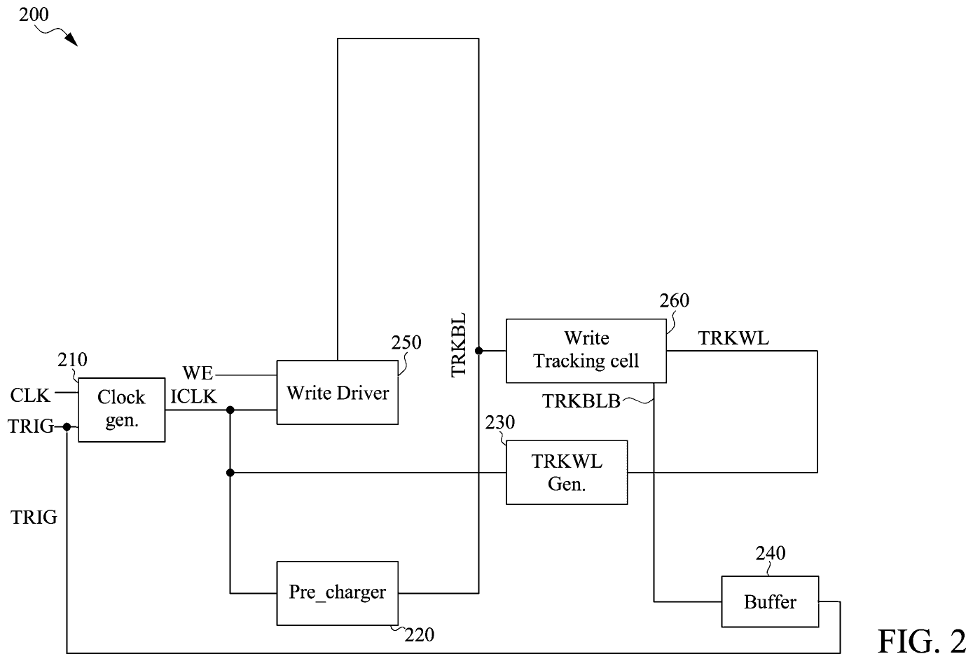

As a representative example, the memory controller 105 can include a clock generator, a pre-charger, a TRKWL generator, and a buffer. In some embodiments, the clock generator can receive a clock (CLK) signal, and provide, based on the CLK signal, an internal clock (ICLK) signal with a rising edge. The rising edge is configured for a write driver (upon receiving a write enable signal) to perform a write operation on a nominal memory cell, for the pre-charger to cease pre-charging a TRKBL coupled to a write tracking cell, for the TRKWL generator to pull up a TRKWL signal. In response to the TRKWL signal transitioning to a logic 1, at least one corresponding write tracking cell can be activated, causing a TRKBL signal (e.g., the voltage present on the TRKBL) to be pulled down and a TRKBLB signal (e.g., the voltage present on the TRKBLB) to be pulled up, respectively. The memory controller 105 can provide a trigger (TRIG) signal through the buffer to the clock generator, in which the TRIG signal can closely follow the TRKBLB signal. Upon the TRIG signal being pulled up, the clock generator can pull down the ICLK signal, which causes the write operation (performed by the write driver) to be ceased accordingly. For example, the falling edge of the ICLK signal can cause a WL signal applied on a WL operatively coupled to the nominal memory cell to be pulled down. Stated another way, a pulse width of the WL signal can be adjusted based on the TRIG signal (or the TRKBLB signal). Various implementations of the memory controller 105 will be discussed in further detail with respect to FIGS. 2, 3, 4, 5, 6, 7, 8, and 9, respectively.

In some embodiments, the memory device 100 can further include various other circuit components such as, for example, a write (or WL) driver/controller 160, an input/output (I/O) circuit 170, etc., each of which may be embodied as logic circuits, analog circuits, or a combination of them. The write driver 160 can provide a voltage or current conducted through one or more word lines WL of the memory array 120. Such a voltage/current may sometimes be referred to as a WL signal. The memory controller 105 can utilize the adjusted ICLK signal to adjust the pulse width of this WL signal (as briefly discussed above). The I/O circuit 170 can sense a voltage or current conducted through one or more bit lines BLs of the memory array 120. For example, the I/O circuit 170 may include a number of sense amplifiers, each of which is operatively coupled to one or more of the bit lines BLs inside the memory array 120.

FIGS. 2, 3, 4, 5, 6, 7, 8, and 9 illustrate block diagrams of various implementations 200, 300, 400, 500, 600, 700, 800, and 900 of the memory controller 105 (FIG. 1), respectively, in accordance with various embodiments. Hereinafter, the implementations 200, 300, 400, 500, 600, 700, 800, and 900 are referred to as “controller 200”, “controller 300,” “controller 400,” “controller 500,” “controller 600,” “controller 700,” “controller 800,” and “controller 900,” respectively.

As a brief overview, during an operation (e.g., a write operation or a read operation) performed on a nominal memory cell, the disclosed memory controller (e.g., one of the controllers 200 to 900) can adjust the timing to pull down an internal clock (ICLK) signal (i.e., the timing of a falling edge of the ICLK signal), based on a trigger (TRIG) signal that closely follows either the signal present on a TRKBLB (a TRKBLB signal) or the signal present on a TRKBL (a TRKBL signal). With the adjusted timing on the falling edge of the ICLK signal, the write/read operation can be more efficiently performed.

Referring first to FIG. 2, the controller 200 includes a clock generator 210, a pre-charger 220, a TRKWL generator 230, and a buffer 240. Further, a write driver 250 (a part of the write driver 160 in FIG. 1) and a write tracking cell 260 (a part of the tracking cell 135 in FIG. 1) are operatively coupled to the controller 200. It should be understood that the block diagram of FIG. 2 has been simplified for illustrative purposes, and the controller 200 (or the memory device 100) can include any of various other components, while remaining within the scope of the present disclosure. For example, the controller 200 can include a pre-discharger configured to pre-discharge a TRKBLB, prior to an operation performed on a corresponding nominal memory cell.

The clock generator 210 includes two inputs configured to receive a clock (CLK) signal and a trigger (TRIG) signal, respectively, and one output to provide an internal clock (ICLK) signal. The write driver 250 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. The write driver 250 can be further coupled to (e.g., controlled by) a voltage present on a TRKBL, which is sometimes referred to as a TRKBL signal. The pre-charger 220 includes one input configured to receive the ICLK signal, and is further coupled to the TRKBL. The write tracking cell 260 is coupled between the TRKBL and a TRKBLB, on which a voltage is present is sometimes referred to as a TRKBLB signal. The pre-charger 220 may pre-charge the TRKBL signal to a logic 1 (while the TRKBLB signal may be pre-discharged to a logic 0), prior to any operation performed on a nominal memory cell, in some embodiments. The pre-charger 220 may cease pre-charging, upon identifying a rising edge of the ICLK signal, in some embodiments.

The TRKWL generator 230 can provide a signal conducted through a TRKWL (a TRKWL signal), based on the ICLK signal. For example, the TRKWL generator 230 can pull up the TRKWL signal, upon identifying a rising edge of the ICLK signal. Once the TRKWL signal being pulled up to a logic 1 or a substantially high voltage level, the write tracking cell 260 can be activated. The write tracking cell 260, upon being activated, can emulate the write operation performed on the nominal memory cell. In some embodiments, similar to the nominal memory cell being programmed (or written), the activated write tracking cell 260 can cause the pre-charged TRKBL signal and the pre-discharged TRKBLB signal, which respectively emulate the signals conducted through a bit line BL and a bit line bar BLB of the nominal memory cell, to fall and rise, respectively.

In some embodiments, the buffer 240 can couple the TRKBLB to one of the inputs of the clock generator 210 that receives the TRIG signal. In other words, the TRIG signal can closely follow the TRKBLB signal. Once a falling edge of the TRIG signal being detected (e.g., by the clock generator 210), the clock generator 210 can pull down the ICLK signal. With the ICLK signal being pulled down (e.g., to a logic 0), an ongoing operation (e.g., a write operation) performed on a nominal memory cell can be ceased. For example, a WL signal provided by the write driver 250 and configured to assert the nominal memory cell can be pulled down, instantly with the TRKBLB signal being pulled down. Stated another way, no additional delay circuit is needed to adjust the timing to pull down a WL signal. Consequently, a pulse width of the WL signal can be shortened.

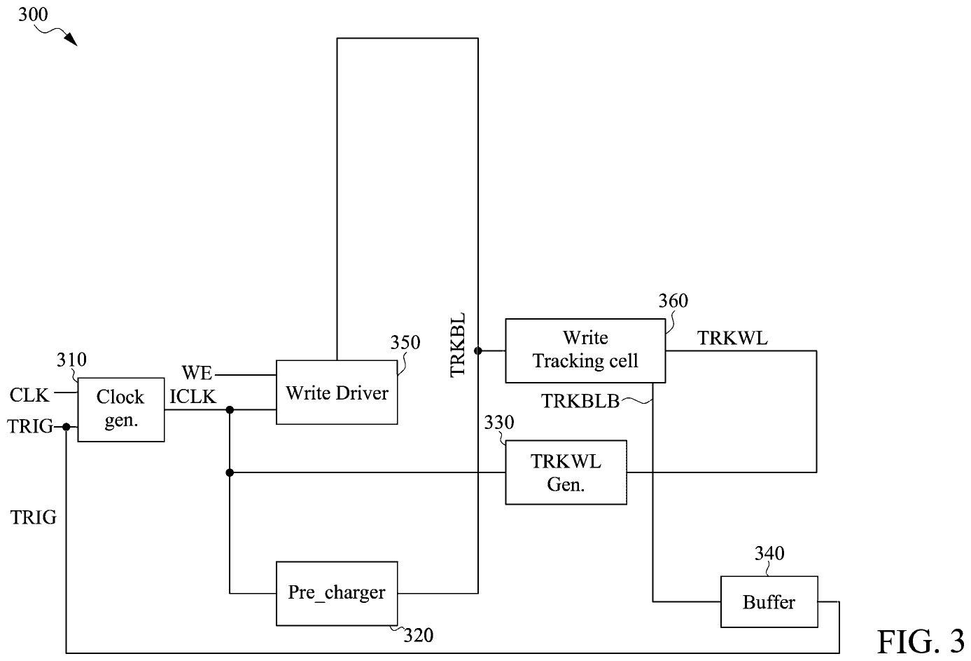

Referring next to FIG. 3, the controller 300 includes a clock generator 310, a pre-charger 320, a TRKWL generator 330, and a buffer 340. Further, a write driver 350 (a part of the write driver 160 in FIG. 1) and a write tracking cell 360 (a part of the tracking cell 135 in FIG. 1) are operatively coupled to the controller 300. The controller 300 is substantially similar to the controller 200, except that the TRKWL generator 330 is operatively coupled to a TRKBL. It should be understood that the block diagram of FIG. 3 has been simplified for illustrative purposes, and the controller 300 (or the memory device 100) can include any of various other components, while remaining within the scope of the present disclosure. For example, the controller 300 can include a pre-discharger configured to pre-discharge a TRKBLB, prior to an operation performed on a corresponding nominal memory cell.

The clock generator 310 includes two inputs configured to receive a clock (CLK) signal and a trigger (TRIG) signal, respectively, and one output to provide an internal clock (ICLK) signal. The write driver 350 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. The write driver 350 can be further coupled to (e.g., controlled by) a voltage present on a TRKBL, which is sometimes referred to as a TRKBL signal. The pre-charger 320 includes one input configured to receive the ICLK signal, and is further coupled to the TRKBL. The write tracking cell 360 is coupled between the TRKBL and a TRKBLB, on which a voltage is present is sometimes referred to as a TRKBLB signal. The pre-charger 320 may pre-charge the TRKBL signal to a logic 1 (while the TRKBLB signal may be pre-discharged to a logic 0), prior to any operation performed on a nominal memory cell, in some embodiments. The pre-charger 320 may cease pre-charging the TRKBL signal, upon identifying a rising edge of the ICLK signal, in some embodiments.

The TRKWL generator 330 can provide a signal conducted through a TRKWL (a TRKWL signal), based on the TRKBL signal. For example, the TRKWL generator 330 can pull up the TRKWL signal, upon identifying a falling edge of the TRKBL signal. Once the TRKWL signal being pulled up to a logic 1 or a substantially high voltage level, the write tracking cell 360 can be activated. The activated write tracking cell 360, upon being activated, can emulate the write operation performed on the nominal memory cell. In some embodiments, similar to the nominal memory cell being programmed (or written), the activated write tracking cell 360 can cause the pre-charged TRKBL signal and the pre-discharged TRKBLB signal, which respectively emulate the signals conducted through a bit line BL and a bit line bar BLB of the nominal memory cell, to fall and rise, respectively.

In some embodiments, the buffer 340 can couple the TRKBLB to one of the inputs of the clock generator 310 that receives the TRIG signal. In other words, the TRIG signal can closely follow the TRKBLB signal. Once a falling edge of the TRIG signal being detected (e.g., by the clock generator 310), the clock generator 310 can pull down the ICLK signal. With the ICLK signal being pulled down (e.g., to a logic 0), an ongoing operation (e.g., a write operation) performed on a nominal memory cell can be ceased. For example, a WL signal provided by the write driver 350 and configured to assert the nominal memory cell can be pulled down, instantly with the TRKBLB signal being pulled down. Stated another way, no additional delay circuit is needed to adjust the timing to pull down a WL signal. Consequently, a pulse width of the WL signal can be shortened.

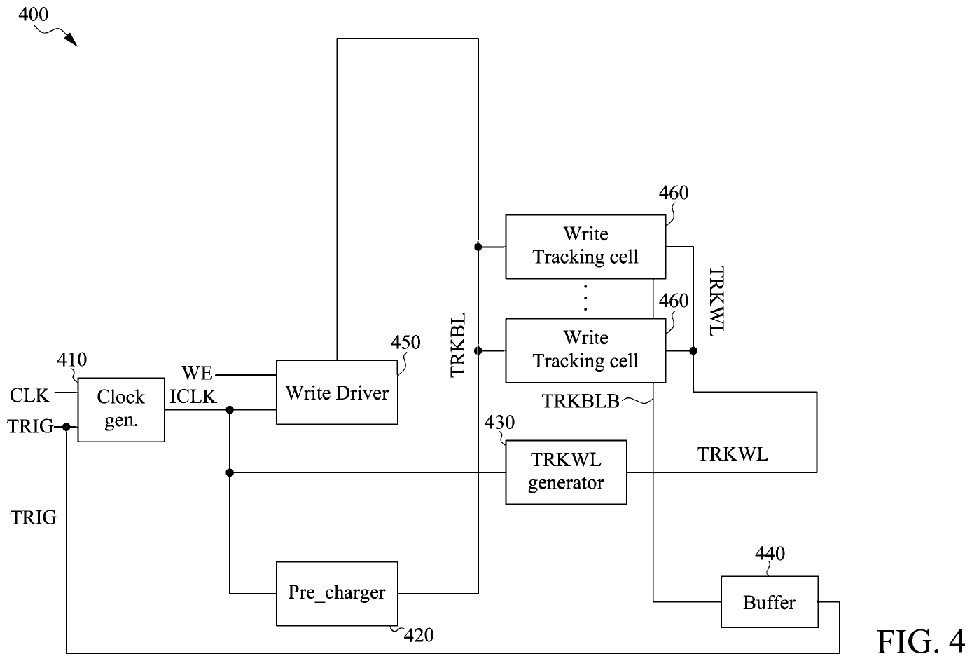

Referring next to FIG. 4, the controller 400 includes a clock generator 410, a pre-charger 420, a TRKWL generator 430, and a buffer 440. Further, a write driver 450 (a part of the write driver 160 in FIG. 1) and multiple write tracking cells 460 (a part of the tracking cell 135 in FIG. 1) are operatively coupled to the controller 400. The controller 400 is substantially similar to the controller 200, except that the controller 400 is operatively coupled to multiple write tracking cells. It should be understood that the block diagram of FIG. 4 has been simplified for illustrative purposes, and the controller 400 (or the memory device 100) can include any of various other components, while remaining within the scope of the present disclosure. For example, the controller 400 can include a pre-discharger configured to pre-discharge a TRKBLB, prior to an operation performed on a corresponding nominal memory cell.

The clock generator 410 includes two inputs configured to receive a clock (CLK) signal and a trigger (TRIG) signal, respectively, and one output to provide an internal clock (ICLK) signal. The write driver 450 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. The write driver 450 can be further coupled to (e.g., controlled by) a voltage present on a TRKBL, which is sometimes referred to as a TRKBL signal. The pre-charger 420 includes one input configured to receive the ICLK signal, and is further coupled to the TRKBL. The write tracking cells 460 are each coupled between the TRKBL and a TRKBLB, on which a voltage is present is sometimes referred to as a TRKBLB signal. The pre-charger 420 may pre-charge the TRKBL signal to a logic 1 (while the TRKBLB signal may be pre-discharged to a logic 0), prior to any operation performed on a nominal memory cell, in some embodiments. The pre-charger 420 may cease pre-charging the TRKBL signal, upon identifying a rising edge of the ICLK signal, in some embodiments.

The TRKWL generator 430 can provide a signal conducted through a TRKWL (a TRKWL signal), based on the ICLK signal. For example, the TRKWL generator 430 can pull up the TRKWL signal, upon identifying a rising edge of the ICLK signal. Once the TRKWL signal being pulled up to a logic 1 or a substantially high voltage level, the write tracking cells 460 can be activated. The activated write tracking cell 460, upon being activated, can emulate the write operation performed on the nominal memory cell. In some embodiments, similar to the nominal memory cell being programmed (or written), the activated write tracking cell 460 can cause the pre-charged TRKBL signal and the pre-discharged TRKBLB signal, which respectively emulate the signals conducted through a bit line BL and a bit line bar BLB of the nominal memory cell, to fall and rise, respectively. The number of write tracking cells 460 is inversely proportional to local variation of the tracking cells, in accordance with some embodiments. For example, local variation of the tracking cells may be reduced by \sqrt{N} times, where N represents the number of write tracking cells 460.

In some embodiments, the buffer 440 can couple the TRKBLB to one of the inputs of the clock generator 410 that receives the TRIG signal. In other words, the TRIG signal can closely follow the TRKBLB signal. Once a falling edge of the TRIG signal being detected (e.g., by the clock generator 410), the clock generator 410 can pull down the ICLK signal. With the ICLK signal being pulled down (e.g., to a logic 0), an ongoing operation (e.g., a write operation) performed on a nominal memory cell can be ceased. For example, a WL signal provided by the write driver 450 and configured to assert the nominal memory cell can be pulled down, instantly with the TRKBLB signal being pulled down. Stated another way, no additional delay circuit is needed to adjust the timing to pull down a WL signal. Consequently, a pulse width of the WL signal can be shortened.

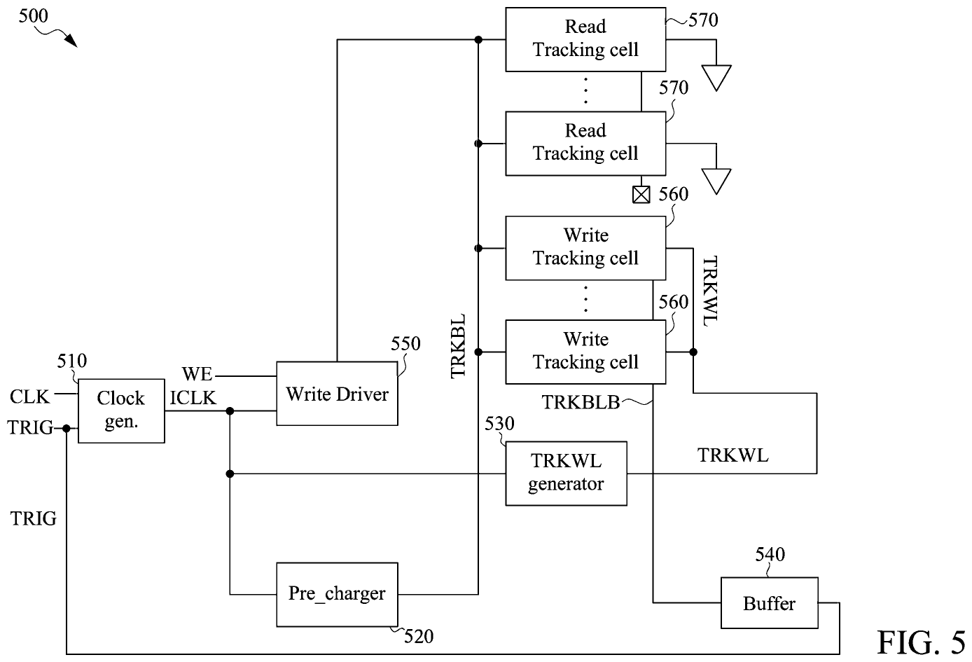

Referring next to FIG. 5, the controller 500 includes a clock generator 510, a pre-charger 520, a TRKWL generator 530, and a buffer 540. Further, a write driver 550 (a part of the write driver 160 in FIG. 1), multiple write tracking cells 560 (a part of the tracking cell 135 in FIG. 1), and one or more dummy cells 570 (a part of the dummy cell 140 in FIG. 1) are operatively coupled to the controller 500. The controller 500 is substantially similar to the controller 400, except that the controller 500 is operatively coupled further to a number of dummy cells. It should be understood that the block diagram of FIG. 5 has been simplified for illustrative purposes, and the controller 500 (or the memory device 100) can include any of various other components, while remaining within the scope of the present disclosure. For example, the controller 500 can include a pre-discharger configured to pre-discharge a TRKBLB, prior to an operation performed on a corresponding nominal memory cell.

The clock generator 510 includes two inputs configured to receive a clock (CLK) signal and a trigger (TRIG) signal, respectively, and one output to provide an internal clock (ICLK) signal. The write driver 550 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. The write driver 550 can be further coupled to (e.g., controlled by) a voltage present on a TRKBL, which is sometimes referred to as a TRKBL signal. The pre-charger 520 includes one input configured to receive the ICLK signal, and is further coupled to the TRKBL. The write tracking cells 560 are each coupled between the TRKBL and a TRKBLB, on which a voltage is present is sometimes referred to as a TRKBLB signal. The pre-charger 520 may pre-charge the TRKBL signal to a logic 1 (while the TRKBLB signal may be pre-discharged to a logic 0), prior to any operation performed on a nominal memory cell, in some embodiments. The pre-charger 520 may cease pre-charging the TRKBL signal, upon identifying a rising edge of the ICLK signal, in some embodiments.

The TRKWL generator 530 can provide a signal conducted through a TRKWL (a TRKWL signal), based on the ICLK signal. For example, the TRKWL generator 530 can pull up the TRKWL signal, upon identifying a rising edge of the ICLK signal. Once the TRKWL signal being pulled up to a logic 1 or a substantially high voltage level, the write tracking cells 560 can be activated. The activated write tracking cell 560, upon being activated, can emulate the write operation performed on the nominal memory cell. In some embodiments, similar to the nominal memory cell being programmed (or written), the activated write tracking cell 560 can cause the pre-charged TRKBL signal and the pre-discharged TRKBLB signal, which respectively emulate the signals conducted through a bit line BL and a bit line bar BLB of the nominal memory cell, to fall and rise, respectively. The number of write tracking cells 560 is inversely proportional to local variation of the tracking cells, in accordance with some embodiments. For example, local variation of the tracking cells may be reduced by \sqrt{N} times, where N represents the number of write tracking cells 560. Different from the write tracking cell 560, the dummy cell 570 may not be coupled to the TRKWL. For example, respective gate terminals of access (or pass-gate) transistors of the write tracking cell 560 are connected to the TRKWL, while respective gate terminals of access (or pass-gate) transistors of the dummy cell 570 are connected to ground (e.g., VSS).

In some embodiments, the buffer 540 can couple the TRKBLB to one of the inputs of the clock generator 510 that receives the TRIG signal. In other words, the TRIG signal can closely follow the TRKBLB signal. Once a falling edge of the TRIG signal being detected (e.g., by the clock generator 510), the clock generator 510 can pull down the ICLK signal. With the ICLK signal being pulled down (e.g., to a logic 0), an ongoing operation (e.g., a write or read operation) performed on a nominal memory cell can be ceased. For example, a WL signal provided by the write driver 550 and configured to assert the nominal memory cell can be pulled down, instantly with the TRKBLB signal being pulled down. Stated another way, no additional delay circuit is needed to adjust the timing to pull down a WL signal. Consequently, a pulse width of the WL signal can be shortened.

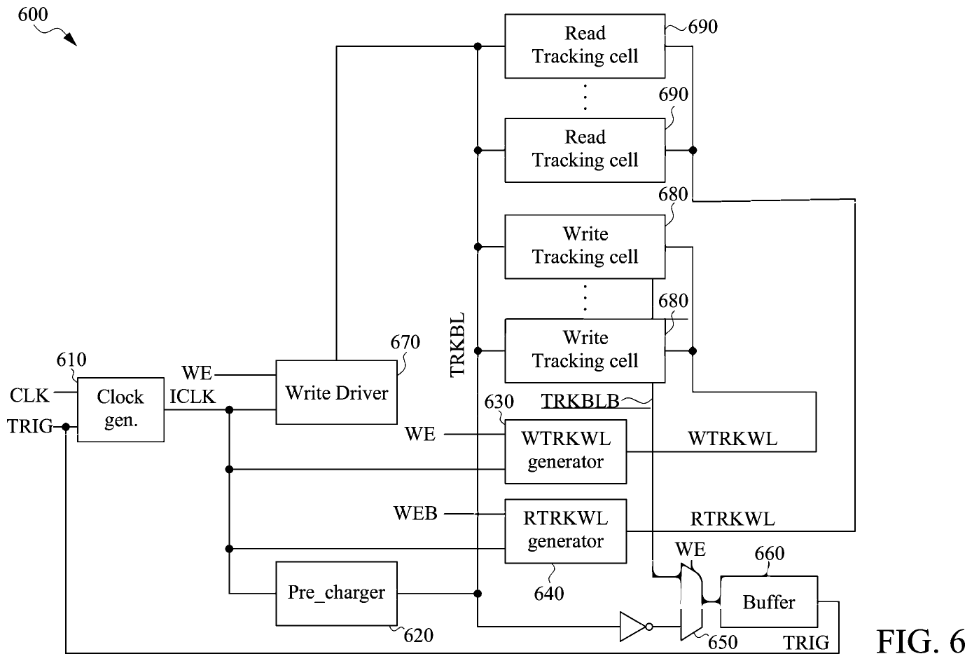

Referring next to FIG. 6, the controller 600 includes a clock generator 610, a pre-charger 620, a write (WTRKWL) generator 630, a read (RTRKWL) generator 640, a multiplexer 650, and a buffer 660. Further, a write driver 670 (a part of the write driver 160 in FIG. 1), and one or more write tracking cells 680 and one or more read tracking cells 690 (a part of the tracking cell 135 in FIG. 1) are operatively coupled to the controller 600. The controller 600 is substantially similar to the controller 200, except that the controller 600 further includes a RTRKWL generator and is operatively coupled further to a number of read tracking cells. It should be understood that the block diagram of FIG. 6 has been simplified for illustrative purposes, and the controller 600 (or the memory device 100) can include any of various other components, while remaining within the scope of the present disclosure. For example, the controller 600 can include a pre-discharger configured to pre-discharge a TRKBLB, prior to an operation performed on a corresponding nominal memory cell.

The clock generator 610 includes two inputs configured to receive a clock (CLK) signal and a trigger (TRIG) signal, respectively, and one output to provide an internal clock (ICLK) signal. The write driver 650 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. Logically inverse to the WE signal, the controller 600 can also receive a WEB signal inputted to the RTRKWL generator 640. The write driver 650 can be further coupled to (e.g., controlled by) a voltage present on a TRKBL, which is sometimes referred to as a TRKBL signal. The pre-charger 620 includes one input configured to receive the ICLK signal, and is further coupled to the TRKBL. The write tracking cells 680 are each coupled between the TRKBL and a TRKBLB, on which a voltage is present is sometimes referred to as a TRKBLB signal. The pre-charger 620 may pre-charge the TRKBL signal to a logic 1 (while the TRKBLB signal may be pre-discharged to a logic 0), prior to any operation performed on a nominal memory cell, in some embodiments. The pre-charger 620 may cease pre-charging the TRKBL signal, upon identifying a rising edge of the ICLK signal, in some embodiments.

During a write operation performed on the nominal memory cell (e.g., the WE signal and the WEB signal being provided at a logic 1 and a logic 0, respectively), the WTRKWL generator 630 can provide a signal conducted through a write tracking word line WTRKWL (a WTRKWL signal), based on the ICLK signal and the WE signal. For example, the WTRKWL generator 630 can pull up the WTRKWL signal, upon identifying a rising edge of the ICLK signal and the WE signal being asserted to a logic 1. Once the WTRKWL signal being pulled up to a logic 1 or a substantially high voltage level, the write tracking cells 680 can be activated. The write tracking cell 680, upon being activated, can emulate the write operation performed on the nominal memory cell. In some embodiments, similar to the nominal memory cell being programmed (or written), the activated write tracking cell 680 can cause the pre-charged TRKBL signal and the pre-discharged TRKBLB signal, which respectively emulate the signals conducted through a bit line BL and a bit line bar BLB of the nominal memory cell, to fall and rise, respectively.

During a read operation performed on the nominal memory cell (e.g., the WE signal and the WEB signal being provided at a logic 0 and a logic 1, respectively), the RTRKWL generator 640 can provide a signal conducted through a read tracking word line RTRKWL (a RTRKWL signal), based on the ICLK signal and the WEB signal. For example, the RTRKWL generator 640 can pull up the RTRKWL signal, upon identifying a rising edge of the ICLK signal and the WEB signal being asserted to a logic 1. Stated another way, the WTRKWL generator 630 and RTRKWL generator 640 may be activated alternately. Once the RTRKWL signal being pulled up to a logic 1 or a substantially high voltage level, the read tracking cells 690 can be activated. The read tracking cell 690, upon being activated, can emulate the read operation performed on the nominal memory cell. In some embodiments, similar to the nominal memory cell being read, the activated read tracking cell 690 can cause the pre-charged TRKBL signal, which emulates the signal conducted through a bit line BL of the nominal memory cell, to fall.

In some embodiments, the multiplexer 650, controlled by the WE signal, includes two inputs coupled to the TRKBLB and the TRKBL, respectively, and one output coupled to the buffer 660. For example, when the WE signal being provided at a logic 1, the multiplexer 650 may select the TRKBLB signal as its output to the buffer 660; and when the WE signal being provided at a logic 0, the multiplexer 650 may select the TRKBL signal as its output to the buffer 660. Further, the TRKBL may be coupled to the input of the multiplexer 650 through an inverter. The buffer 660 can couple the selected TRKBLB or TRKBL (being inverted) to one of the inputs of the clock generator 610 that receives the TRIG signal. In other words, the TRIG signal can closely follow the TRKBLB signal or the inverted TRKBL signal.

Once a falling edge of the TRIG signal being detected (e.g., by the clock generator 610), the clock generator 610 can pull down the ICLK signal. With the ICLK signal being pulled down (e.g., to a logic 0), an ongoing operation (e.g., a write or read operation) performed on a nominal memory cell can be ceased. For example, a WL signal provided by the write driver 670 and configured to assert the nominal memory cell can be pulled down, instantly with the TRKBLB or TRKBL signal transitioning to a different logic state. Stated another way, no additional delay circuit is needed to adjust the timing to pull down a WL signal. Consequently, a pulse width of the WL signal can be shortened.

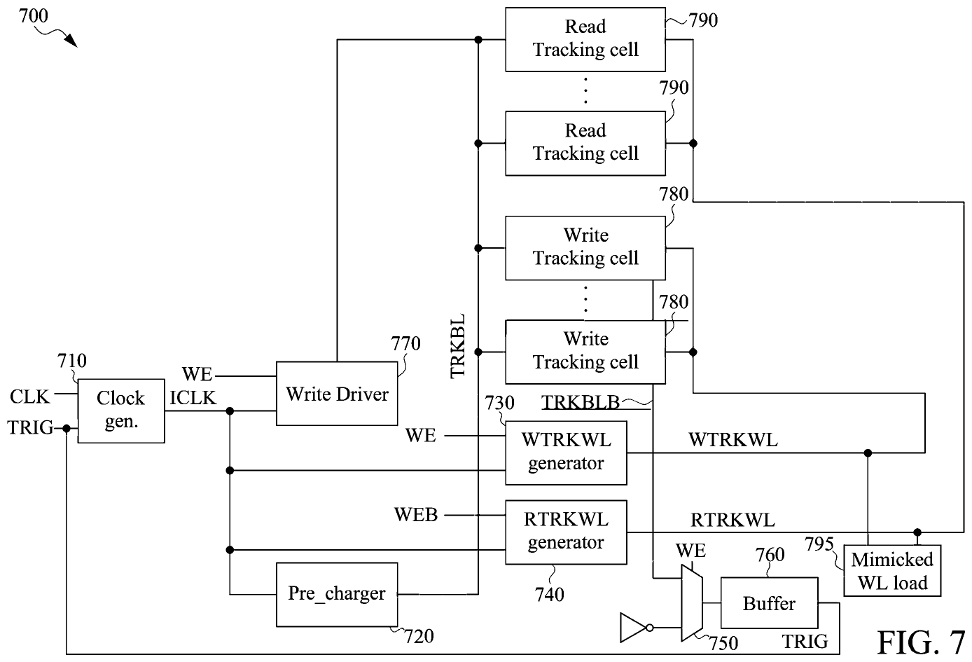

Referring next to FIG. 7, the controller 700 includes a clock generator 710, a pre-charger 720, a WTRKWL generator 730, a RTRKWL generator 740, a multiplexer 750, and a buffer 760. Further, a write driver 770 (a part of the write driver 160 in FIG. 1), and one or more write tracking cells 780 and one or more read tracking cells 790 (a part of the tracking cell 135 in FIG. 1) are operatively coupled to the controller 700. The WTRKWL generator 730 is coupled to each of the write tracking cells 780 through a WTRKWL, with a mimicked WL load 795 coupled to the WTRKWL; and the RTRKWL generator 740 is coupled to each of the read tracking cells 790 through a RTRKWL, with the mimicked WL load 795 coupled to the RTRKWL. The controller 700 is substantially similar to the controller 700, except that the controller 700 is operatively coupled further to the mimicked WL load. It should be understood that the block diagram of FIG. 7 has been simplified for illustrative purposes, and the controller 700 (or the memory device 100) can include any of various other components, while remaining within the scope of the present disclosure. For example, the controller 700 can include a pre-discharger configured to pre-discharge a TRKBLB, prior to an operation performed on a corresponding nominal memory cell.

The mimicked WL load 795 is configured to provide the write and/or RTRKWL with a similar resistance and a similar capacitance to a nominal word line WL of the memory array. In some embodiments, the mimicked WL load 795 includes a plurality of gates coupled to the read and WTRKWLs. In some embodiments, the gates are arranged in parallel with a row of the memory array. In some embodiments, the gate terminals have the same pitch as the gate terminals of access (pass-gate) transistors to which the nominal word line WL is connected. This arrangement of gates is convenient in terms of chip design, layout, and accurate mimicking of the WL capacitance.

The clock generator 710 includes two inputs configured to receive a clock (CLK) signal and a trigger (TRIG) signal, respectively, and one output to provide an internal clock (ICLK) signal. The write driver 750 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. Logically inverse to the WE signal, the controller 700 can also receive a WEB signal inputted to the RTRKWL generator 740. The write driver 750 can be further coupled to (e.g., controlled by) a voltage present on a TRKBL, which is sometimes referred to as a TRKBL signal. The pre-charger 720 includes one input configured to receive the ICLK signal, and is further coupled to the TRKBL. The write tracking cells 780 are each coupled between the TRKBL and a TRKBLB, on which a voltage is present is sometimes referred to as a TRKBLB signal. The pre-charger 720 may pre-charge the TRKBL signal to a logic 1 (while the TRKBLB signal may be pre-discharged to a logic 0), prior to any operation performed on a nominal memory cell, in some embodiments. The pre-charger 720 may cease pre-charging the TRKBL signal, upon identifying a rising edge of the ICLK signal, in some embodiments.

During a write operation performed on the nominal memory cell (e.g., the WE signal and the WEB signal being provided at a logic 1 and a logic 0, respectively), the WTRKWL generator 730 can provide a signal conducted through the WTRKWL (a WTRKWL signal), based on the ICLK signal and the WE signal. For example, the WTRKWL generator 730 can pull up the WTRKWL signal, upon identifying a rising edge of the ICLK signal and the WE signal being asserted to a logic 1. Once the WTRKWL signal being pulled up to a logic 1 or a substantially high voltage level, the write tracking cells 780 can be activated. The write tracking cell 780, upon being activated, can emulate the write operation performed on the nominal memory cell. In some embodiments, similar to the nominal memory cell being programmed (or written), the activated write tracking cell 780 can cause the pre-charged TRKBL signal and the pre-discharged TRKBLB signal, which respectively emulate the signals conducted through a bit line BL and a bit line bar BLB of the nominal memory cell, to fall and rise, respectively.

During a read operation performed on the nominal memory cell (e.g., the WE signal and the WEB signal being provided at a logic 0 and a logic 1, respectively), the RTRKWL generator 740 can provide a signal conducted through a RTRKWL (a RTRKWL signal), based on the ICLK signal and the WEB signal. For example, the RTRKWL generator 740 can pull up the RTRKWL signal, upon identifying a rising edge of the ICLK signal and the WEB signal being asserted to a logic 1. Stated another way, the WTRKWL generator 730 and RTRKWL generator 740 may be activated alternately. Once the RTRKWL signal being pulled up to a logic 1 or a substantially high voltage level, the read tracking cells 790 can be activated. The read tracking cell 790, upon being activated, can emulate the read operation performed on the nominal memory cell. In some embodiments, similar to the nominal memory cell being read, the activated read tracking cell 790 can cause the pre-charged TRKBL signal, which emulates the signal conducted through a bit line BL of the nominal memory cell, to fall.

In some embodiments, the multiplexer 750, controlled by the WE signal, includes two inputs coupled to the TRKBLB and the TRKBL, respectively, and one output coupled to the buffer 760. For example, when the WE signal being provided at a logic 1, the multiplexer 750 may select the TRKBLB signal as its output to the buffer 760; and when the WE signal being provided at a logic 0, the multiplexer 750 may select the TRKBL signal as its output to the buffer 760. Further, the TRKBL may be coupled to the input of the multiplexer 750 through an inverter. The buffer 760 can couple the selected TRKBLB or TRKBL (being inverted) to one of the inputs of the clock generator 710 that receives the TRIG signal. In other words, the TRIG signal can closely follow the TRKBLB signal or the inverted TRKBL signal.

Once a falling edge of the TRIG signal being detected (e.g., by the clock generator 710), the clock generator 710 can pull down the ICLK signal. With the ICLK signal being pulled down (e.g., to a logic 0), an ongoing operation (e.g., a write or read operation) performed on a nominal memory cell can be ceased. For example, a WL signal provided by the write driver 770 and configured to assert the nominal memory cell can be pulled down, instantly with the TRKBLB or TRKBL signal transitioning to a different logic state. Stated another way, no additional delay circuit is needed to adjust the timing to pull down a WL signal. Consequently, a pulse width of the WL signal can be shortened.

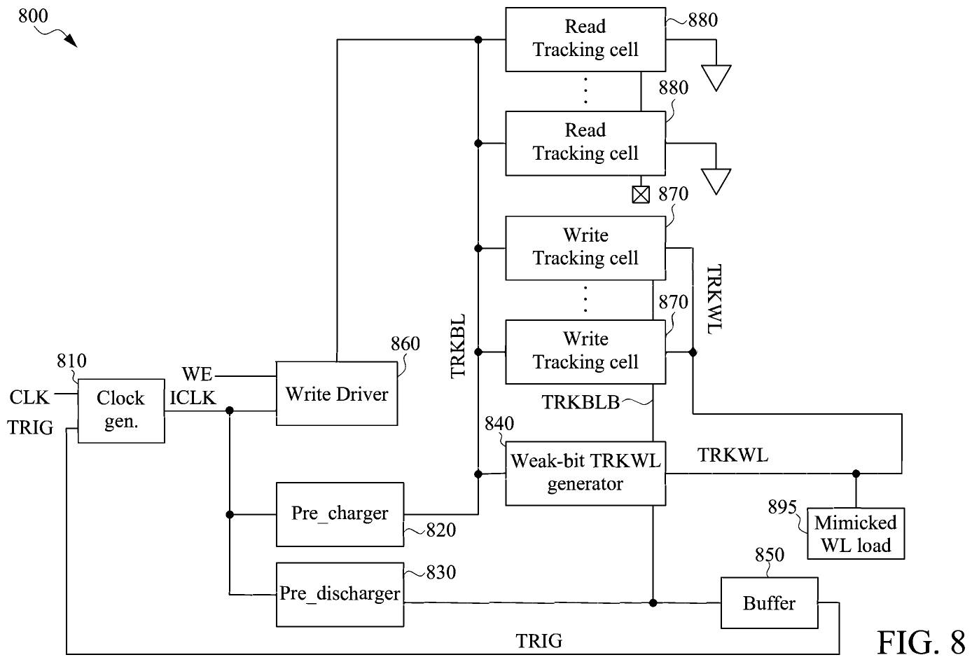

Referring next to FIG. 8, the controller 800 includes a clock generator 810, a pre-charger 820, a pre-discharger 830, a TRKWL generator 840, and a buffer 850. Further, a write driver 860 (a part of the write driver 160 in FIG. 1), multiple write tracking cells 870 (a part of the tracking cell 135 in FIG. 1), and one or more dummy cells 880 (a part of the dummy cell 140 in FIG. 1) are operatively coupled to the controller 800. The TRKWL generator 840 is coupled to each of the write tracking cells 870 through a TRKWL, with a mimicked WL load 895 coupled to the TRKWL. It should be understood that the block diagram of FIG. 8 has been simplified for illustrative purposes, and the controller 800 (or the memory device 100) can include any of various other components, while remaining within the scope of the present disclosure.

The clock generator 810 includes two inputs configured to receive a clock (CLK) signal and a trigger (TRIG) signal, respectively, and one output to provide an internal clock (ICLK) signal. The write driver 860 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. The write driver 860 can be further coupled to (e.g., controlled by) a voltage present on a TRKBL, which is sometimes referred to as a TRKBL signal. The pre-charger 820 includes one input configured to receive the ICLK signal, and is further coupled to the TRKBL. The write tracking cells 870 are each coupled between the TRKBL and a TRKBLB, on which a voltage is present is sometimes referred to as a TRKBLB signal. The pre-discharger 830 includes one input configured to receive the ICLK signal, and is further coupled to the TRKBLB. The pre-charger 820 may pre-charge the TRKBL signal to a logic 1 and the pre-discharger 830 may pre-discharge the TRKBLB signal to a logic 0, respectively, prior to any operation performed on a nominal memory cell, in some embodiments. The pre-charger 820 may cease pre-charging the TRKBL signal and the pre-discharger 830 may cease pre-discharging the TRKBLB signal, respectively, upon identifying a rising edge of the ICLK signal, in some embodiments.

The TRKWL generator 840 can provide a signal conducted through a TRKWL (a TRKWL signal), based on the ICLK signal. For example, the TRKWL generator 840 can pull up the TRKWL signal, upon identifying a rising edge of the ICLK signal. Once the TRKWL signal being pulled up to a logic 1 or a substantially high voltage level, the write tracking cells 870 can be activated. The activated write tracking cell 870, upon being activated, can emulate the write operation performed on the nominal memory cell. In some embodiments, similar to the nominal memory cell being programmed (or written), the activated write tracking cell 870 can cause the pre-charged TRKBL signal and the pre-discharged TRKBLB signal, which respectively emulate the signals conducted through a bit line BL and a bit line bar BLB of the nominal memory cell, to fall and rise, respectively.

The number of write tracking cells 870 is inversely proportional to local variation of the tracking cells, in accordance with some embodiments. For example, local variation of the tracking cells may be reduced by \sqrt{N} times, where N represents the number of write tracking cells 870. Different from the write tracking cell 870, the dummy cell 880 may not be coupled to the TRKWL. For example, respective gate terminals of access (or pass-gate) transistors of the write tracking cell 870 are connected to the TRKWL, while respective gate terminals of access (or pass-gate) transistors of the dummy cell 880 are connected to ground (e.g., VSS).

In some embodiments, the buffer 850 can couple the TRKBLB to one of the inputs of the clock generator 810 that receives the TRIG signal. In other words, the TRIG signal can closely follow the TRKBLB signal. Once a falling edge of the TRIG signal being detected (e.g., by the clock generator 810), the clock generator 810 can pull down the ICLK signal. With the ICLK signal being pulled down (e.g., to a logic 0), an ongoing operation (e.g., a write or read operation) performed on a nominal memory cell can be ceased. For example, a WL signal provided by the write driver 860 and configured to assert the nominal memory cell can be pulled down, instantly with the TRKBLB signal being pulled down. Stated another way, no additional delay circuit is needed to adjust the timing to pull down a WL signal. Consequently, a pulse width of the WL signal can be shortened.

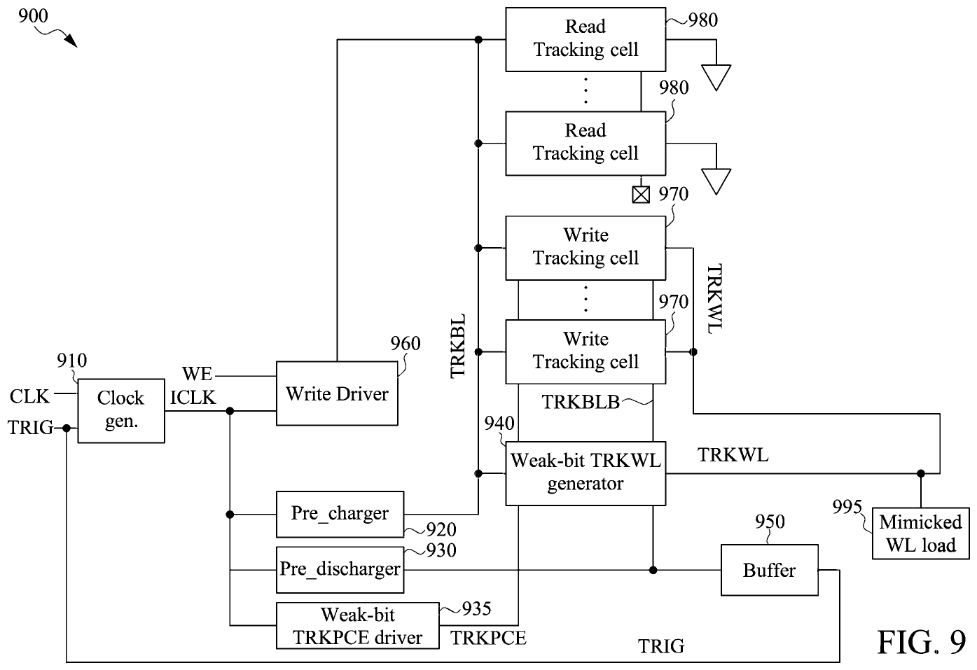

Referring next to FIG. 9, the controller 900 includes a clock generator 910, a pre-charger 920, a pre-discharger 930, a TRKPCE driver 935, a TRKWL generator 940, and a buffer 950. Further, a write driver 960 (a part of the write driver 160 in FIG. 1), multiple write tracking cells 970 (a part of the tracking cell 135 in FIG. 1), and one or more dummy cells 980 (a part of the dummy cell 140 in FIG. 1) are operatively coupled to the controller 900. The TRKWL generator 940 is coupled to each of the write tracking cells 970 through a TRKWL, with a mimicked WL load 995 coupled to the TRKWL. It should be understood that the block diagram of FIG. 9 has been simplified for illustrative purposes, and the controller 900 (or the memory device 100) can include any of various other components, while remaining within the scope of the present disclosure.

The clock generator 910 includes two inputs configured to receive a clock (CLK) signal and a trigger (TRIG) signal, respectively, and one output to provide an internal clock (ICLK) signal. The write driver 960 includes two inputs configured to receive the ICLK signal and a write enable (WE) signal, respectively. The WE signal may be asserted to a logic 1 configured for performing a write operation on a nominal memory cell or a logic 0 configured for performing a read operation on a nominal memory cell. The write driver 960 can be further coupled to (e.g., controlled by) a voltage present on a TRKBL, which is sometimes referred to as a TRKBL signal.

The write tracking cells 970 are each coupled between the TRKBL and a TRKBLB, and further coupled to a TRKPCE, in which voltages present on the TRKBLB and on the TRKPCE are sometimes referred to as a TRKBLB signal and a TRKPCE signal, respectively. The pre-charger 920 includes one input configured to receive the ICLK signal, and is further coupled to the TRKBL. The pre-discharger 930 includes one input configured to receive the ICLK signal, and is further coupled to the TRKBLB. The TRKPCE driver 935 includes one input configured to receive the ICLK signal, and is further coupled to the TRKPCE. The pre-charger 920 may pre-charge the TRKBL signal to a logic 1 and the pre-discharger 930 may pre-discharge the TRKBLB signal to a logic 0, respectively, prior to any operation performed on a nominal memory cell. The pre-charger 920 may cease pre-charging the TRKBL signal and the pre-discharger 930 may cease pre-discharging the TRKBLB signal, respectively, upon identifying a rising edge of the ICLK signal, in some embodiments. The TRKPCE driver 935 may pull up the TRKPCE signal, upon identifying a rising edge of the ICLK signal.

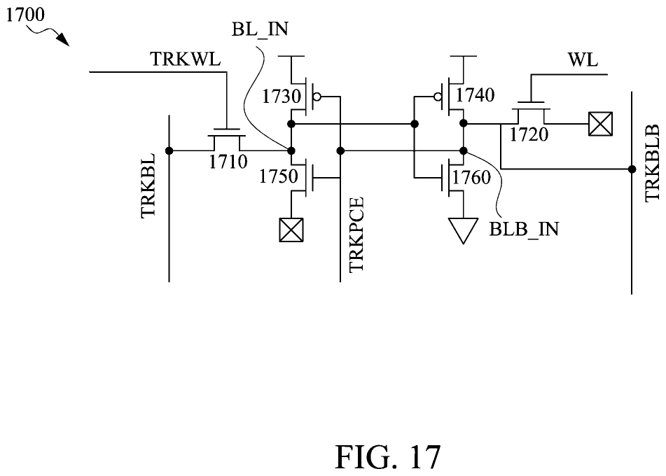

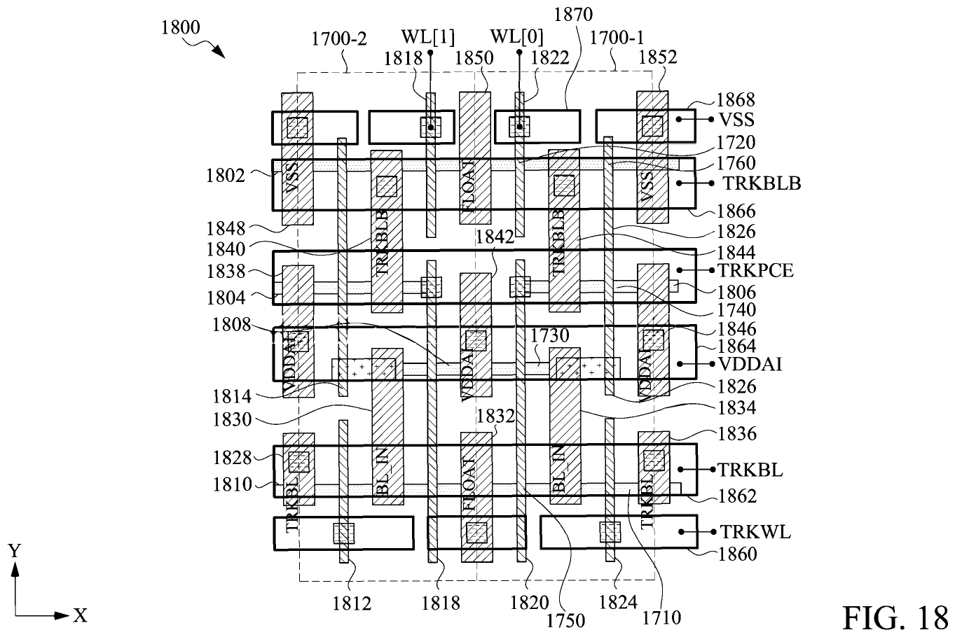

As will be discussed below in FIGS. 17-18, the TRKPCE can be connected to the respective gate terminals of a pull-up transistor and a pull-down transistor of at least one of the write tracking cells 970, which allows the TRKPCE driver 935 or the TRKPCE signal to emulate the contention between the pull-up transistor and the pull-down transistor of a nominal memory cell. Such a contention may be even distinguishable when the nominal memory cell is a weak or weaken memory cell (e.g., a memory cell having its pull-down and pull-up transistor(s) with a lower or deteriorated threshold voltage (With) and/or its pass-gate transistor(s) with a higher Vₜₕ, when compared to other normal nominal memory cells).

The TRKWL generator 940 can provide a signal conducted through a TRKWL (a TRKWL signal), based on the ICLK signal. For example, the TRKWL generator 940 can pull up the TRKWL signal, upon identifying a rising edge of the ICLK signal. Once the TRKWL signal being pulled up to a logic 1 or a substantially high voltage level, the write tracking cells 970 can be activated. The activated write tracking cell 970, upon being activated, can emulate the write operation performed on the nominal memory cell. In some embodiments, similar to the nominal memory cell being programmed (or written), the activated write tracking cell 970 can cause the pre-charged TRKBL signal and the pre-discharged TRKBLB signal, which respectively emulate the signals conducted through a bit line BL and a bit line bar BLB of the nominal memory cell, to fall and rise, respectively.

The number of write tracking cells 970 is inversely proportional to local variation of the tracking cells, in accordance with some embodiments. For example, local variation of the tracking cells may be reduced by \sqrt{N} times, where N represents the number of write tracking cells 970. Different from the write tracking cell 970, the dummy cell 980 may not be coupled to the TRKWL. For example, respective gate terminals of access (or pass-gate) transistors of the write tracking cell 970 are connected to the TRKWL, while respective gate terminals of access (or pass-gate) transistors of the dummy cell 980 are connected to ground (e.g., VSS).

In some embodiments, the buffer 950 can couple the TRKBLB to one of the inputs of the clock generator 910 that receives the TRIG signal. In other words, the TRIG signal can closely follow the TRKBLB signal. Once a falling edge of the TRIG signal being detected (e.g., by the clock generator 910), the clock generator 910 can pull down the ICLK signal. With the ICLK signal being pulled down (e.g., to a logic 0), an ongoing operation (e.g., a write or read operation) performed on a nominal memory cell can be ceased. For example, a WL signal provided by the write driver 960 and configured to assert the nominal memory cell can be pulled down, instantly with the TRKBLB signal being pulled down. Stated another way, no additional delay circuit is needed to adjust the timing to pull down a WL signal. Consequently, a pulse width of the WL signal can be shortened.

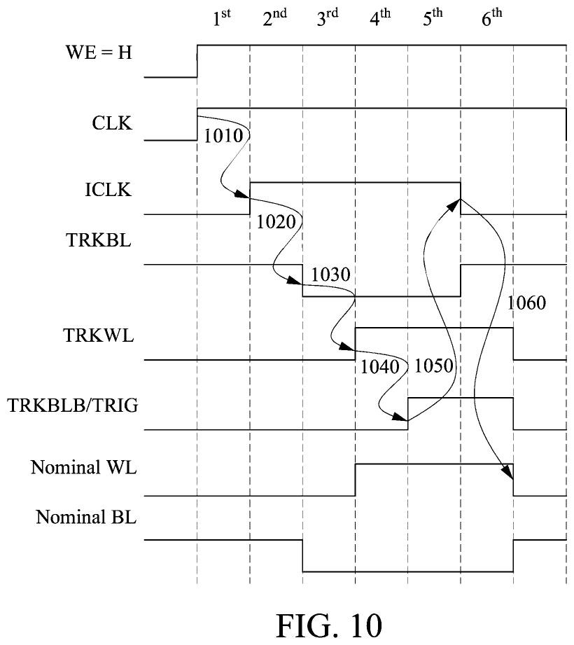

FIG. 10 illustrate example waveforms of various signals, the WE signal, the CLK signal, the ICLK signal, the TRKBL signal, the TRKWL signal, the TRKBLB signal, the TRIG signal, and voltages respectively present on the nominal WL and nominal BL of an asserted nominal memory cell 125, varying over certain time periods when the disclosed memory controller 105 is operating, in accordance with some embodiments. For example, the waveforms shown FIG. 10 may correspond to the signals presented by the controller 300 of FIG. 3. It should be understood the waveforms of FIG. 10 are provided for illustrating relative transitions among the signals, and thus, respective scales of the signals may vary while reaming within the scope of the present disclosure.

As shown, the signals may vary over six time periods, which may collectively correspond to a writable operation performed on the asserted nominal memory cell 125. During (or at the beginning of) the 1^{st} time period, the WE signal is provided as transitioning from a logic 0 to a logic 1, which allows the asserted nominal memory cell 125 to be programmed. About the same timing when the WE signal is pulled up, the CLK signal is pulled up from a logic 0 to a logic 1. During (or at the beginning of) the 2^{nd} time period, the clock generator 310 identifies a rising edge of the CLK signal and thus pulls up the ICLK signal, as indicated by arrow 1010. In some embodiments, during the 1^{st} and 2^{nd} time periods (e.g., prior to actually programming the asserted nominal memory cell 125), the TRKBL signal and the TRBLB signal are kept at a logic 1 and a logic 0, respectively, as shown in FIG. 10.

During (or at the beginning of) the 3^{rd} time period, the pre-charger 320 identifies a rising edge of the ICLK signal and thus ceases holding the voltage level present on the TRKBL, causing the TRKBL signal to fall, as indicated by arrow 1020. About the same timing when the TRKBL signal starts to fall, the voltage level present on the nominal BL falls. Stated another way, the TRKBL signal tracks a timing of the voltage level present on the nominal BL. During (or at the beginning of) the 4^{th} time period, the TRKWL generator 330 identifies a falling edge of the TRKBL signal and thus pulls up the TRKWL signal, as indicated by arrow 1030. About the same timing when the TRKWL signal starts to rise, the voltage level present on the nominal WL rises. Stated another way, the TRKWL signal tracks a timing of the voltage level present on the nominal WL. In some embodiments, when the voltage level on the nominal WL is pulled up, the pass-gate transistors of the asserted nominal memory cell 125 are activated or turned on, which allows the asserted nominal memory cell 125 to be programmed. Concurrently, the write tracking cell 360 are also activated or turned on (by the pulled-up TRKWL signal). Accordingly, the TRKBLB signal may start to rise.

For example, during (or at the beginning of) the 5^{th} time period, the TRKBLB signal is pulled up to a logic 1, as incited by arrow 1040. In some embodiments, the TRIG signal closely follows the TRKBLB signal. Upon identifying that the TRKBLB/TRIG signal transitions to a logic 1, the clock generator 310 can pull down the ICLK signal, as indicated by arrow 1050. During (or at the beginning of) the 6^{th} time period, upon identifying that the ICLK signal transitions back to a logic 0, the write driver 350 can pull down the voltage level present on the nominal WL (also pull down the TRKWL signal), as incited by arrow 1060. Consequently, the access to program the nominal memory cell 125 can be terminated, and the write tracking cell 360 is also deactivated or turned off. In some embodiments, the TRKBL may be re-charged to a logic 1 (i.e., not wait until the TRKWL signal transitioning back to a logic 0), as shown in FIG. 10.

FIG. 11 illustrates an example circuit diagram of some components of the memory device 100, in accordance with some embodiments. The circuit diagram of FIG. 11 includes one of the write tracking cells 135 (FIG. 1), a part of the write driver 160 (FIG. 1), and a part of the controller 105 (FIG. 1). For example, the circuit diagram of FIG. 11 may correspond to the controller 300 of FIG. 3, together with the operatively coupled write tracking cell 360 and write driver 350. It should be understood that the circuit diagram of FIG. 11 is provided for illustrative purposes and does not necessarily intend to limit the scope of the present disclosure.

As shown in FIG. 11, the pre-charger 320 of the controller 300 is implemented as a PMOS transistor 1104, and the controller 300 further includes an NMOS transistor 1106 serving as its pre-discharger. Based on the ICLK signal, the transistor 1104 is configured to pre-charge the TRKBL, and the transistor 1106 is configured to pre-discharge the TRKBLB. For example, respective gate terminals of the transistor 1104 and the transistor 1106 are configured to receive the ICLK signal (from the clock generator 310 not shown in FIG. 11) through two inverters and one inverter, respectively. The write driver 350, coupled to the controller 300, may be implemented as another NMOS transistor 1102, with its gate terminal configured to receive the ICLK signal through two inverters. As such, when the ICLK signal transitions from a logic 0 to a logic 1, the transistor (write driver) 1102, the transistor (pre-charger) 1104, and the transistor (pre-discharger) 1106 can be turned on, off, and off, respectively, which causes the pre-charged TRKBL signal to fall and the pre-discharged TRKBLB signal to rise.

Referring still to FIG. 11, an example implementation of the write tracking cell 360 is shown. The write tracking cell 360 includes NMOS transistors 1108 and 1114, and PMOS transistors 1110 and 1112. In some embodiments, the transistor 1108 may emulate one of the pass-gate transistors of the nominal memory cell connected to a bit line BL, the transistor 1110 may emulate one of the pull-up transistors of the nominal memory cell, the transistor 1112 may emulate the other pull-up transistor of the nominal memory cell, and the transistor 1114 may emulate one of the pull-down transistors of the nominal memory cell. The transistors 1112 and 1114 may serve as an inverter, with an input (BL_IN node) coupled to the TRKBL through the transistor 1108 and an output connected to the TRKBLB. The transistor 1108 is gated by the TRKWL signal, and the transistor 1110 is gated by (or coupled to) the TRKBLB signal.

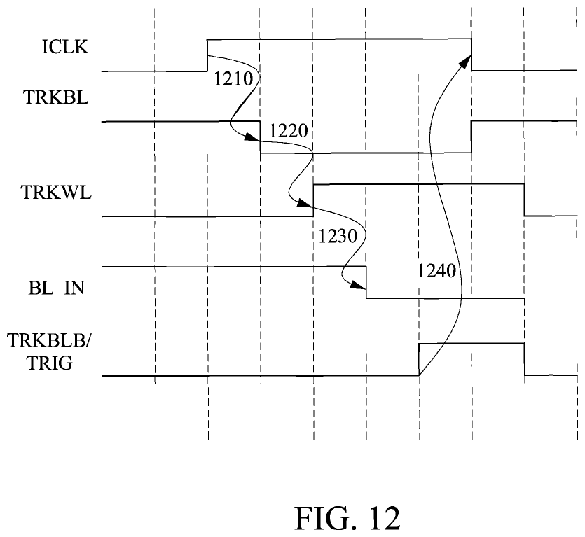

FIG. 12 illustrate example waveforms of various signals, the ICLK signal, the TRKBL signal, the TRKWL signal, the TRKBLB signal, a voltage level present on the BL_IN node (BL_IN signal), and the TRIG signal, varying over certain time periods when the controller 300 (implemented according to the example circuit diagram of FIG. 11) is operating, in accordance with some embodiments. The waveforms of FIG. 12 are substantially similar to those shown in FIG. 10, and thus, the following discussion will be mainly focused on the difference.

As shown, a rising edge of the ICLK signal causes the TRKBL signal to fall (arrow 1210), and a falling edge of the TRKBL signal causes the TRKWL signal to rise (arrow 1220). When the TRKBL signal transitions to (or stays at) a logic 0 and the TRKWL signal transitions to (or stays at) a logic 1, respectively, the BL_IN signal may be pulled down. However, the logically low TRKBLB signal may pull up the BL_IN signal, which causes a contention between the TRKBL signal the TRKBLB signal. Upon the TRKBLB signal transitions to a logic 1, the ICLK signal can be pulled down back to a logic 0. Consequently, the transistor (write driver) 1102, the transistor (pre-charger) 1104, and the transistor (pre-discharger) 1106 can be turned off, on, and on, respectively. Accordingly, the current write operation may be ceased, and the TRKBL and TRKBLB may be again pre-charged and pre-discharged to a logic 1 and a logic 0, respectively, prior to the next operation.

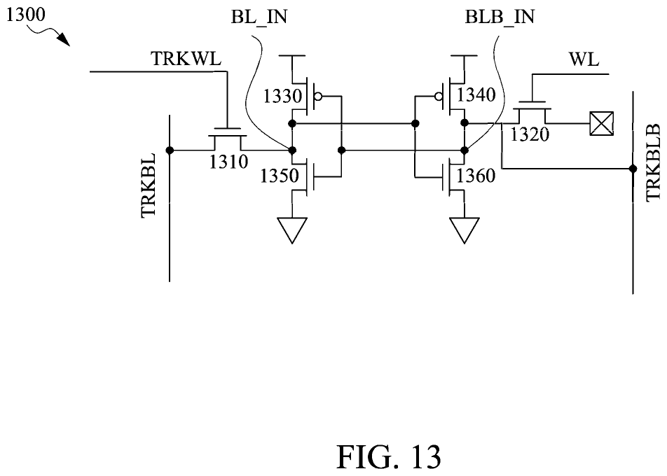

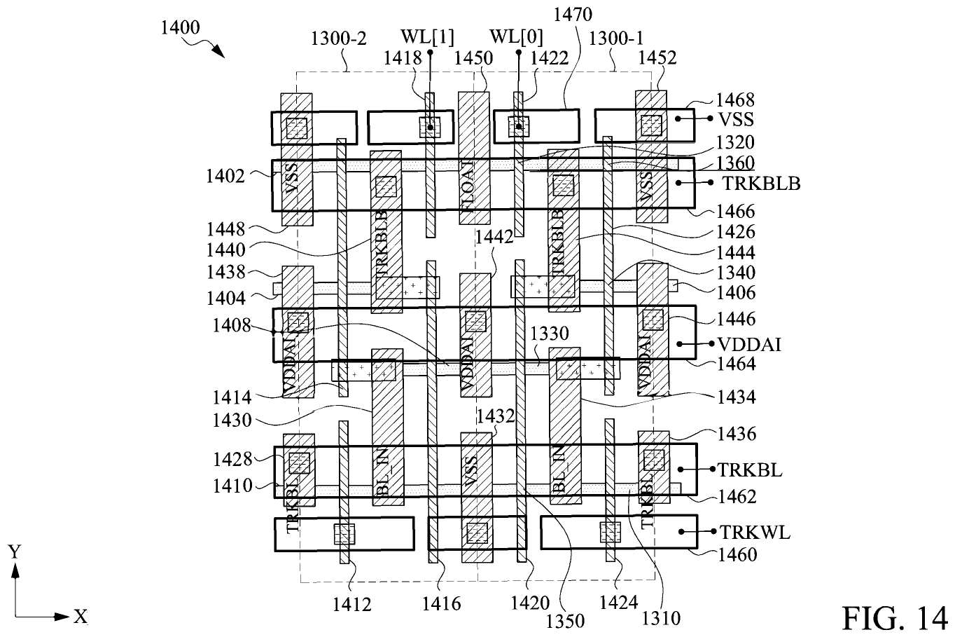

FIG. 13 illustrates another example circuit diagram of one of the write tracking cells 135 (FIG. 1), in accordance with some embodiments. Hereinafter, the circuit diagram of FIG. 13 is referred to as write tracking cell 1300. For example, the write tracking cells 260 (FIG. 2), 360 (FIG. 3), 460 (FIG. 4), 560 (FIG. 5), 680 (FIG. 6), 780 (FIG. 7), and 870 (FIG. 8) may each be implemented as the write tracking cell 1300 shown in FIG. 13. FIG. 14 illustrates an example layout 1400 that can be utilized to fabricate two of the write tracking cells 1300 shown in FIG. 13, e.g., 1300-1 and 1300-2. It should be understood that the circuit diagram of FIG. 13 and the corresponding layout shown in FIG. 14 are provided for illustrative purposes and does not necessarily intend to limit the scope of the present disclosure.

In some embodiments, the write tracking cell 1300 is substantially similar to one of the nominal memory cells implemented in a 6T SRAM configuration. For example, in FIG. 13, the write tracking cell 1300 also includes NMOS pass-gate (PG) transistors, 1310 and 1320, PMOS pull-up (PU) transistors 1330 and 1340, and NMOS pull-down (PD) transistors 1350 and 1360. In some embodiments, one of the PG transistors 1310 may have its gate terminal connected to a TRKWL, while the other one of the PG transistors 1320 may have it gate terminal connected to a nominal word line WL. Further, a drain terminal of the PG transistor 1310 is connected to a TRKBL and a source terminal of the PG transistor 1310 is connected to an output (BL_IN node) of a first inverter formed by the pull-up transistor 1330 and pull-down transistor 1350; and a drain terminal of the PG transistor 1320 is electrically floating and a source terminal of the PG transistor 1320, which is connected to an output (BLB_IN node) of a second inverter formed by the pull-up transistor 1340 and the pull-down transistor 1360 and is further connected to a TRKBLB. An input of the first inverter is connected to the BLB_IN node; and an input of the second inverter is connected to the BL_IN node.

Referring next to FIG. 14, the layout 1400 includes patterns 1402, 1404, 1406, 1408, and 1410 configured to form active regions (sometimes referred to as oxide diffusion/definition regions), and patterns 1412, 1414, 1416, 1418, 1420, 1422, 1424, and 1426 configured to form gate terminals, respectively. Hereinafter, the patterns 1402 to 1410 are referred to as active regions 1402 to 1410, respectively, and the patterns 1412 to 1426 are referred to as gate terminals 1412 to 1426, respectively. In some embodiments, the active regions 1402 to 1410 may each extend along the X-direction, while the gate terminals 1412 to 1426 may each extend along the Y-direction. In some embodiments, the active regions 1402 to 1410 and the gate terminals 1412 to 1426 can form a number (e.g., 12) of transistors operatively configured for two 6T SRAM cells.

For example, as indicated in FIG. 14, the active region 1410 and the gate terminal 1420 can form the PD transistor 1350; the active region 1410 and the gate terminal 1424 can form the PG transistor 1310; the active region 1408 and the gate terminal 1420 can form the PU transistor 1330; the active region 1402 and the gate terminal 1426 can form the PD transistor 1360; the active region 1402 and the gate terminal 1422 can form the PG transistor 1320; and the active region 1406 and the gate terminal 1426 can form the PU transistor 1340.

The layout 1400 further includes patterns 1428, 1430, 1432, 1434, 1436, 1438, 1440, 1442, 1444, 1446, 1448, 1450, and 1452 configured to from conductive source/drain connection structures (sometimes referred to as MDs), respectively. Hereinafter, the patterns 1428 to 1452 are referred to as MDs 1428 to 1452, respectively. In some embodiments, the MDs 1428 to 1452 may each extend along the Y-direction, and further, each of the MDs 1428 to 1452 may be overlapped with (e.g., electrically coupled to) a portion of a corresponding active region that operatively serves as a source or drain terminal of the corresponding transistor.

For example, as indicated in FIG. 14, the MD 1432 can be in contact with one of the source/drain terminals of the PD transistor 1350, which can be electrically coupled to a metal track that carries VSS; the MD 1434 can be in contact with the other one of the source/drain terminals of the PD transistor 1350 and one of the source/drain terminals of the PG transistor 1310, which can be configured as the BL_IN node; the MD 1436 can be in contact with the other one of the source/drain terminals of the PG transistor 1310, which can be electrically coupled to a metal track that serves as the TRKBL; the MD 1442 can be in contact with one of the source/drain terminals of the PU transistor 1330, which can be electrically coupled to a metal track that carries VDD; the MD 1446 can be in contact with one of the source/drain terminals of the PU transistor 1340, which can be electrically coupled to a metal track that carries VDD; the MD 1444 can be in contact with one of the source/drain terminals of the PD transistor 1360 and one of the source/drain terminals of the PG transistor 1320, which can be configured as the BLB_IN node that can be electrically coupled to a metal track that serves as the TRKBLB; the MD 1450 can be in contact with the other one of the source/drain terminals of the PG transistor 1320, which is electrically floating; and the MD 1452 can be in contact with the other one of the source/drain terminals of the PD transistor 1360, which can be electrically coupled to a metal track that carries VSS.

The layout 1400 further includes patterns 1460, 1462, 1464, 1466, 1468, and 1470 configured to from metal tracks disposed in a metallization layer M0, respectively. The metallization layer M0 is generally referred to as a bottommost one of a plurality of metallization layers disposed over the frontside surface of a substrate where the active regions and gate terminals are formed. Hereinafter, the patterns 1460 to 1470 are referred to as M0 tracks 1462 to 1470, respectively. In some embodiments, the M0 tracks 1462 to 1470 may each extend along the X-direction, and further, each of the M0 tracks 1462 to 1470 may be overlapped with (e.g., coupled to) one or more MDs or one or more gate terminals.

For example, as indicated in FIG. 14, the M0 track 1460 can be coupled to the gate terminal 1424 (e.g., the gate terminal of the PG transistor 1310), which can be configured as the TRKWL; the M0 track 1462 can be coupled to the MD 1436 (e.g., the drain terminal of the PG transistor 1310), which can be configured as the TRKBL; the M0 track 1464 can be coupled to the MDs 1442 and 1446 (e.g., the respective source terminals of the PU transistors 1330 and 1340), which can be configured as a part of a power rail carrying VDD; the M0 track 1466 can be coupled to the MD 1444 (e.g., the source terminal of the PG transistor 1320), which can be configured as the TRKBLB; the M0 track 1468 can be coupled to the MD 1452 (e.g., the source terminal of the PD transistor 1360), which can be configured as a part of a power rail carrying VSS; and the M0 track 1470 can be coupled to the gate terminal 1422 (e.g., the gate terminal of the PG transistor 1320), which can be configured as the nominal word line WL (e.g., WL[0]).

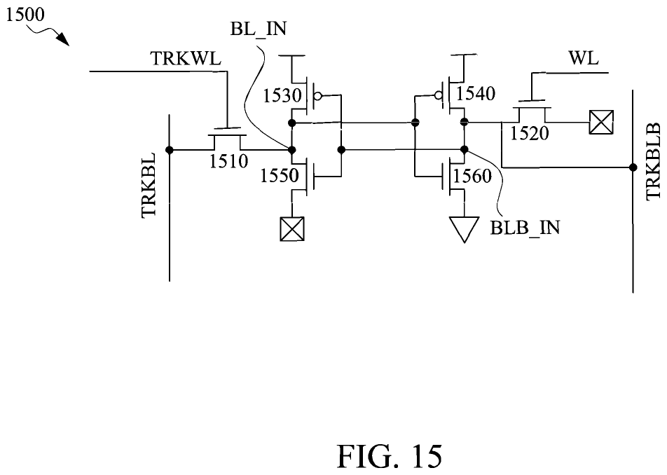

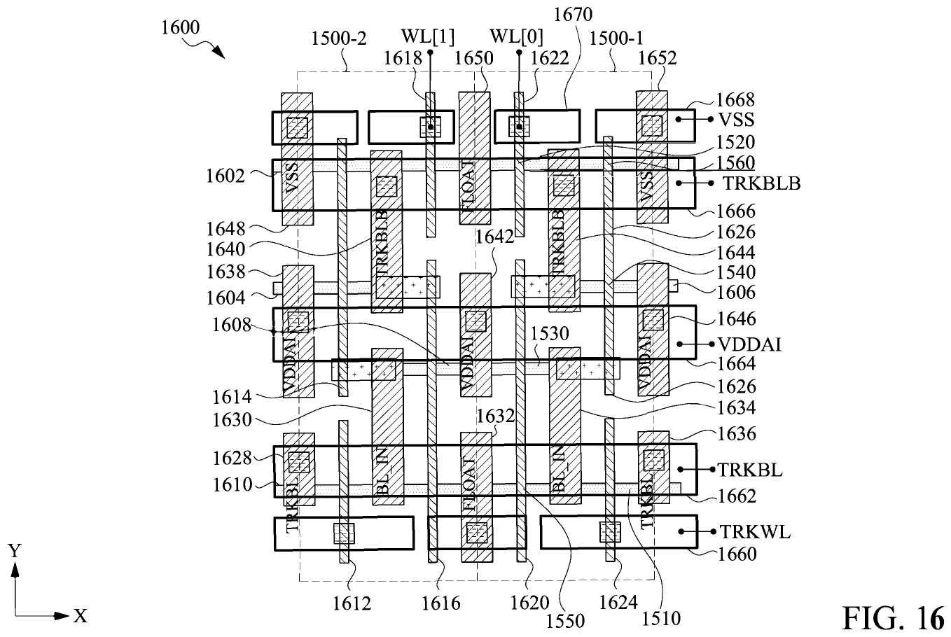

FIG. 15 illustrates yet another example circuit diagram of one of the write tracking cells 135 (FIG. 1), in accordance with some embodiments. Hereinafter, the circuit diagram of FIG. 15 is referred to as write tracking cell 1500. For example, the write tracking cells 260 (FIG. 2), 360 (FIG. 3), 460 (FIG. 4), 560 (FIG. 5), 680 (FIG. 6), 780 (FIG. 7), and 870 (FIG. 8) may each be implemented as the write tracking cell 1300 shown in FIG. 15. FIG. 16 illustrates an example layout that can be utilized to fabricate two of the write tracking cells 1500 shown in FIG. 15, e.g., 1500-1 and 1500-2. It should be understood that the circuit diagram of FIG. 15 and the corresponding layout shown in FIG. 16 are provided for illustrative purposes and does not necessarily intend to limit the scope of the present disclosure.

In some embodiments, the write tracking cell 1500 is substantially similar to one of the nominal memory cells implemented in a 6T SRAM configuration. For example, in FIG. 15, the write tracking cell 1500 also includes NMOS pass-gate (PG) transistors, 1510 and 1520, PMOS pull-up (PU) transistors 1530 and 1540, and NMOS pull-down (PD) transistors 1550 and 1560. In some embodiments, one of the PG transistors 1510 may have its gate terminal connected to a TRKWL, while the other one of the PG transistors 1520 may have it gate terminal connected to a nominal word line WL. Further, a drain terminal of the PG transistor 1510 is connected to a TRKBL and a source terminal of the PG transistor 1510 is connected to an output (BL_IN node) of a first inverter formed by the pull-up transistor 1530 and pull-down transistor 1550; and a drain terminal of the PG transistor 1520 is electrically floating and a source terminal of the PG transistor 1520, which is connected to an output (BLB_IN node) of a second inverter formed by the pull-up transistor 1540 and the pull-down transistor 1560 and is further connected to a TRKBLB. An input of the first inverter is connected to the BLB_IN node; and an input of the second inverter is connected to the BL_IN node.

Referring next to FIG. 16, the layout 1600 includes patterns 1602, 1604, 1606, 1608, and 1610 configured to form active regions (sometimes referred to as oxide diffusion/definition regions), and patterns 1612, 1614, 1616, 1618, 1620, 1622, 1624, and 1626 configured to form gate terminals, respectively. Hereinafter, the patterns 1602 to 1610 are referred to as active regions 1602 to 1610, respectively, and the patterns 1612 to 1626 are referred to as gate terminals 1612 to 1626, respectively. In some embodiments, the active regions 1602 to 1610 may each extend along the X-direction, while the gate terminals 1612 to 1626 may each extend along the Y-direction. In some embodiments, the active regions 1602 to 1610 and the gate terminals 1612 to 1626 can form a number (e.g., 12) of transistors operatively configured for two 6T SRAM cells.

For example, as indicated in FIG. 16, the active region 1610 and the gate terminal 1620 can form the PD transistor 1550; the active region 1610 and the gate terminal 1624 can form the PG transistor 1510; the active region 1608 and the gate terminal 1620 can form the PU transistor 1550; the active region 1602 and the gate terminal 1626 can form the PD transistor 1560; the active region 1602 and the gate terminal 1622 can form the PG transistor 1520; and the active region 1606 and the gate terminal 1626 can form the PU transistor 1540.

The layout 1600 further includes patterns 1628, 1630, 1632, 1634, 1636, 1638, 1640, 1642, 1644, 1646, 1648, 1650, and 1652 configured to from conductive source/drain connection structures (sometimes referred to as MDs), respectively. Hereinafter, the patterns 1628 to 1652 are referred to as MDs 1628 to 1652, respectively. In some embodiments, the MDs 1628 to 1652 may each extend along the Y-direction, and further, each of the MDs 1628 to 1652 may be overlapped with (e.g., electrically coupled to) a portion of a corresponding active region that operatively serves as a source or drain terminal of the corresponding transistor.

For example, as indicated in FIG. 16, the MD 1632 can be in contact with one of the source/drain terminals of the PD transistor 1550, which can be electrically floating; the MD 1634 can be in contact with the other one of the source/drain terminals of the PD transistor 1550 and one of the source/drain terminals of the PG transistor 1510, which can be configured as the BL_IN node; the MD 1636 can be in contact with the other one of the source/drain terminals of the PG transistor 1510, which can be electrically coupled to a metal track that serves as the TRKBL; the MD 1642 can be in contact with one of the source/drain terminals of the PU transistor 1530, which can be electrically coupled to a metal track that carries VDD; the MD 1646 can be in contact with one of the source/drain terminals of the PU transistor 1540, which can be electrically coupled to a metal track that carries VDD; the MD 1644 can be in contact with one of the source/drain terminals of the PD transistor 1560 and one of the source/drain terminals of the PG transistor 1520, which can be configured as the BLB_IN node that can be electrically coupled to a metal track that serves as the TRKBLB; the MD 1650 can be in contact with the other one of the source/drain terminals of the PG transistor 1520, which is electrically floating; and the MD 1652 can be in contact with the other one of the source/drain terminals of the PD transistor 1560, which can be electrically coupled to a metal track that carries VSS.

The layout 1600 further includes patterns 1660, 1662, 1664, 1666, 1668, and 1670 configured to from metal tracks disposed in a metallization layer M0, respectively. The metallization layer M0 is generally referred to as a bottommost one of a plurality of metallization layers disposed over the frontside surface of a substrate where the active regions and gate terminals are formed. Hereinafter, the patterns 1660 to 1670 are referred to as M0 tracks 1662 to 1670, respectively. In some embodiments, the M0 tracks 1662 to 1670 may each extend along the X-direction, and further, each of the M0 tracks 1662 to 1670 may be overlapped with (e.g., coupled to) one or more MDs or one or more gate terminals.

For example, as indicated in FIG. 16, the M0 track 1660 can be coupled to the gate terminal 1624 (e.g., the gate terminal of the PG transistor 1510), which can be configured as the TRKWL; the M0 track 1662 can be coupled to the MD 1636 (e.g., the drain terminal of the PG transistor 1510), which can be configured as the TRKBL; the M0 track 1664 can be coupled to the MDs 1642 and 1646 (e.g., the respective source terminals of the PU transistors 1530 and 1540), which can be configured as a part of a power rail carrying VDD; the M0 track 1666 can be coupled to the MD 1644 (e.g., the source terminal of the PG transistor 1520), which can be configured as the TRKBLB; the M0 track 1668 can be coupled to the MD 1652 (e.g., the source terminal of the PD transistor 1560), which can be configured as a part of a power rail carrying VSS; and the M0 track 1670 can be coupled to the gate terminal 1622 (e.g., the gate terminal of the PG transistor 1520), which can be configured as the nominal word line WL (e.g., WL[0]).

In general, for a transistor, a higher threshold voltage (Vₜₕ) results in a lower drain to source current (I_{DS}). More specifically, I_{DS} can be determined to vary, in accordance with the following relationship, where V_{gs} is the gate to source voltage difference, and b and a are factors that are substantially independent of manufacturing variations: I_{DS}=b*(V_{gs}−Vₜₕ)\hat{ }a. According to this equation, lowering V_{gs} has the same effect as increasing Vₜₕ.

In some embodiments of the present disclosure, the TRKWL (e.g., as shown in FIGS. 11, 13, and 15) may be driven with a suppressed voltage and/or the TRKBL (e.g., as shown in FIGS. 11, 13, and 15) may be driven with an increased voltage to mimic the weak nominal memory cell. The weak memory cell generally has at least one of its pass-gate transistors with an abnormally higher Vₜₕ and/or at least one of its pull-up or pull-down transistors with an abnormally lower Vₜₕ. The suppressed TRKWL signal is a voltage held below the driving voltage for a nominal word line WL, and the increased TRKBL signal is a voltage held above the driving voltage for a nominal bit line BL.

The suppressed TRKWL signal (e.g., voltage), applied to the gate terminal of one of the pass-gate transistors of the tracking cell (e.g., 1530 of FIG. 15), is made less than the driving voltage for nominal word line WL, so that V_{gs} of that pass-gate transistor is reduced within the tracking cells. Accordingly, the tracking cells can exhibit the timing of otherwise equivalent memory cells having a pass-gate transistor with a higher Vₜₕ. For example, the voltage applied on the TRKWL is made less by at least a difference between Vₜₕ for the slowest memory cell in the memory array and Vₜₕ for an average memory cell in the memory array. In another example, the voltage applied on the TRKWL is made less than the driving voltage for nominal word lines WLs by four times or more a standard deviation of Vₜₕ among nominal memory cells in the array. In yet another example, the voltage applied on the TRKWL is made less than the driving voltage for nominal word lines WLs by about six times the standard deviation. Similarly, the increased TRKBL signal (e.g., voltage), applied to the gate terminal of one of the pull-up transistors of the tracking cell (e.g., 1540 of FIG. 15), is made higher than the driving voltage for nominal bit line BL, so that V_{gs} of that pull-up transistor is increased within the tracking cells. Accordingly, the tracking cells can exhibit the timing of otherwise equivalent memory cells having a pull-up transistor with a lower Vₜₕ.

FIG. 17 illustrates yet another example circuit diagram of one of the write tracking cells 135 (FIG. 1), in accordance with some embodiments. Hereinafter, the circuit diagram of FIG. 17 is referred to as write tracking cell 1700. For example, the write tracking cells 970 (FIG. 9) may each be implemented as the write tracking cell 1700 shown in FIG. 17. FIG. 18 illustrates an example layout that can be utilized to fabricate two of the write tracking cells 1700 shown in FIG. 17, e.g., 1700-1 and 1700-2. It should be understood that the circuit diagram of FIG. 17 and the corresponding layout shown in FIG. 18 are provided for illustrative purposes and does not necessarily intend to limit the scope of the present disclosure.

In some embodiments, the write tracking cell 1700 is substantially similar to one of the nominal memory cells implemented in a 6T SRAM configuration. For example, in FIG. 17, the write tracking cell 1700 also includes NMOS pass-gate (PG) transistors, 1710 and 1720, PMOS pull-up (PU) transistors 1730 and 1740, and NMOS pull-down (PD) transistors 1750 and 1760. In some embodiments, one of the PG transistors 1710 may have its gate terminal connected to a TRKWL, while the other one of the PG transistors 1720 may have it gate terminal connected to a nominal word line WL. Further, a drain terminal of the PG transistor 1710 is connected to a TRKBL and a source terminal of the PG transistor 1710 is connected to an output (BL_IN node) of a first inverter formed by the pull-up transistor 1730 and pull-down transistor 1750; and a drain terminal of the PG transistor 1720 is electrically floating and a source terminal of the PG transistor 1720, which is connected to an output (BLB_IN node) of a second inverter formed by the pull-up transistor 1740 and the pull-down transistor 1760 and is further connected to a TRKBLB. An input of the first inverter is connected to a TRKPCE; and an input of the second inverter is connected to the BL_IN node.

Referring next to FIG. 18, the layout 1800 includes patterns 1802, 1804, 1806, 1808, and 1810 configured to form active regions (sometimes referred to as oxide diffusion/definition regions), and patterns 1812, 1814, 1816, 1818, 1820, 1822, 1824, and 1826 configured to form gate terminals, respectively. Hereinafter, the patterns 1802 to 1810 are referred to as active regions 1802 to 1810, respectively, and the patterns 1812 to 1826 are referred to as gate terminals 1812 to 1826, respectively. In some embodiments, the active regions 1802 to 1810 may each extend along the X-direction, while the gate terminals 1812 to 1826 may each extend along the Y-direction. In some embodiments, the active regions 1802 to 1810 and the gate terminals 1812 to 1826 can form a number (e.g., 12) of transistors operatively configured for two 6T SRAM cells.

For example, as indicated in FIG. 18, the active region 1810 and the gate terminal 1820 can form the PD transistor 1750; the active region 1810 and the gate terminal 1824 can form the PG transistor 1710; the active region 1808 and the gate terminal 1820 can form the PU transistor 1750; the active region 1802 and the gate terminal 1826 can form the PD transistor 1760; the active region 1802 and the gate terminal 1822 can form the PG transistor 1720; and the active region 1806 and the gate terminal 1826 can form the PU transistor 1740.

The layout 1800 further includes patterns 1828, 1830, 1832, 1834, 1836, 1838, 1840, 1842, 1844, 1846, 1848, 1850, and 1852 configured to from conductive source/drain connection structures (sometimes referred to as MDs), respectively. Hereinafter, the patterns 1828 to 1852 are referred to as MDs 1828 to 1852, respectively. In some embodiments, the MDs 1828 to 1852 may each extend along the Y-direction, and further, each of the MDs 1828 to 1852 may be overlapped with (e.g., electrically coupled to) a portion of a corresponding active region that operatively serves as a source or drain terminal of the corresponding transistor.

For example, as indicated in FIG. 18, the MD 1832 can be in contact with one of the source/drain terminals of the PD transistor 1750, which can be electrically floating; the MD 1834 can be in contact with the other one of the source/drain terminals of the PD transistor 1750 and one of the source/drain terminals of the PG transistor 1710, which can be configured as the BL_IN node; the MD 1836 can be in contact with the other one of the source/drain terminals of the PG transistor 1710, which can be electrically coupled to a metal track that serves as the TRKBL; the MD 1842 can be in contact with one of the source/drain terminals of the PU transistor 1730, which can be electrically coupled to a metal track that carries VDD; the MD 1846 can be in contact with one of the source/drain terminals of the PU transistor 1740, which can be electrically coupled to a metal track that carries VDD; the MD 1844 can be in contact with one of the source/drain terminals of the PD transistor 1760 and one of the source/drain terminals of the PG transistor 1720, which can be configured as the BLB_IN node that can be electrically coupled to a metal track that serves as the TRKBLB; the MD 1850 can be in contact with the other one of the source/drain terminals of the PG transistor 1720, which is electrically floating; and the MD 1852 can be in contact with the other one of the source/drain terminals of the PD transistor 1760, which can be electrically coupled to a metal track that carries VSS.

The layout 1800 further includes patterns 1860, 1862, 1864, 1866, 1868, and 1870 configured to from metal tracks disposed in a metallization layer M0, respectively. The metallization layer M0 is generally referred to as a bottommost one of a plurality of metallization layers disposed over the frontside surface of a substrate where the active regions and gate terminals are formed. Hereinafter, the patterns 1860 to 1870 are referred to as M0 tracks 1862 to 1870, respectively. In some embodiments, the M0 tracks 1862 to 1870 may each extend along the X-direction, and further, each of the M0 tracks 1862 to 1870 may be overlapped with (e.g., coupled to) one or more MDs or one or more gate terminals.

For example, as indicated in FIG. 18, the M0 track 1860 can be coupled to the gate terminal 1824 (e.g., the gate terminal of the PG transistor 1710), which can be configured as the TRKWL; the M0 track 1862 can be coupled to the MD 1836 (e.g., the drain terminal of the PG transistor 1710), which can be configured as the TRKBL; the M0 track 1864 can be coupled to the MDs 1842 and 1846 (e.g., the respective source terminals of the PU transistors 1730 and 1740), which can be configured as a part of a power rail carrying VDD; the M0 track 1866 can be coupled to the gate terminal 1820 (e.g., the respective gate terminals of the transistors 1730 and 1750), which can be configured as the TRKPCE; the M0 track 1868 can be coupled to the MD 1844 (e.g., the source terminal of the PG transistor 1720), which can be configured as the TRKBLB; the M0 track 1870 can be coupled to the MD 1852 (e.g., the source terminal of the PD transistor 1760), which can be configured as a part of a power rail carrying VSS; and the M0 track 1872 can be coupled to the gate terminal 1822 (e.g., the gate terminal of the PG transistor 1720), which can be configured as the nominal word line WL (e.g., WL[0]).

In some embodiments, the TRKPCE signal is utilized to mimic or otherwise control a contention level between the first pull-up transistor and first pull-down transistor of a nominal memory cell connected to a nominal bit line BL. The contention level is typically the voltage present on the BL_IN node (i.e., the output of a first inverter formed by the first pull-up and pull-down transistors). By adjusting the TRKPCE signal (i.e., the voltage applied to an input of the first inverter), the contention level can vary accordingly. Such a contention level can further control operation of a second inverter formed by the second pull-up and second pull-down transistor of the nominal memory cell connected to a nominal bit line bar BLB. Referring again to FIG. 9 and FIG. 17 in conjunction, when the ICLK signal rises, the TRKPCE driver 935 can provide the TRKPCE signal with a suppressed level, so as to emulate a weak memory cell. For example, when the TRKPCE signal is provided with an adjusted (e.g., suppressed) level, the voltage present on the BL_IN node of the tracking cell 1700 can be adjusted (e.g., suppressed) accordingly. As such, a weak memory cell, the pull-up and/or pull-down transistors of which tend to have a lower Vₜₕ, can be emulated.

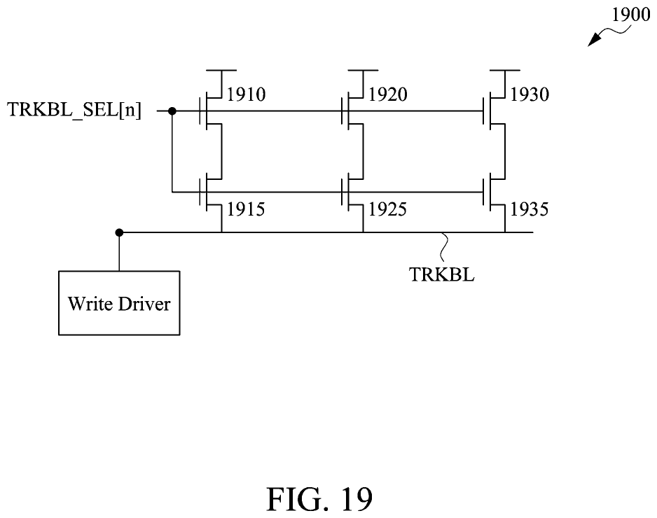

FIG. 19 illustrates an example circuit diagram of an adjustment circuit 1900 coupled to a TRKBL (e.g., the TRKBL shown in FIGS. 2-9), in accordance with various embodiments. A write driver (e.g., the write driver shown in FIGS. 2-9) is also coupled to the TRKBL. Similar to the previous discussions, the adjustment circuit 1900 can adjust (e.g., increase) a voltage level present on the TRKBL, so as to emulate a weak memory cell. As shown, the adjustment circuit 1900 may include a plurality of stacked (e.g., NMOS) transistors, wherein each of the stacked transistors includes at least two transistors, 1910 and 1915, 1920 and 1925, and 1930 and 1935. Specifically, the stacked transistors are each coupled between VDD and a TRKBL. Further, each of the transistors 1910 to 1935 have its gate terminal configured to receive a control signal, TRKBL_SEL[n:0], where in the example of FIG. 19, n is equal to 3. The different stacked transistors may be selectively turned on based on the control signal TRKBL_SEL[n:0].

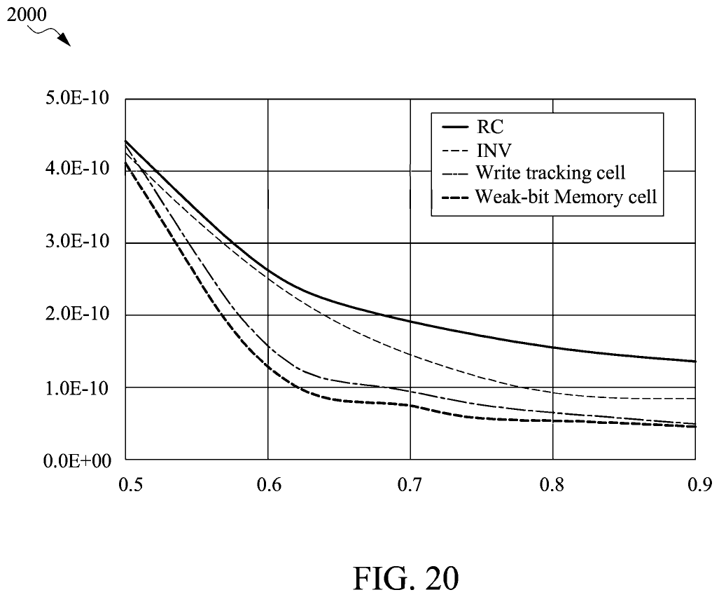

FIG. 20 illustrates a graph 2000 comparing respective merits (e.g., delays) of various memory devices, in accordance with various embodiments. The graph 2000 includes plots 2010, 2020, 2030, and 2040, which correspond to an existing memory device, another existing memory device, a memory device including the controller 500 (FIG. 5), and a memory device including the controller 900 (FIG. 9), respectively. The graph 200 has the X-axis representing different supplied voltages, and the Y-axis representing different tracking delays. As shown, by implementing the disclosed memory controller to perform a tracking scheme on nominal memory cells, the tracking delays can be significantly suppressed. For example, when the supplied voltage is provided at about 0.9 volts (V), a ratio of the tracking delay induced by the controller 500 to a write time of the nominal memory cell is dropped to about 15%. In another example, when the supplied voltage is provided at about 0.9V, a ratio of the tracking delay induced by the controller 900 to a write time of the nominal memory cell is dropped to about 2%.

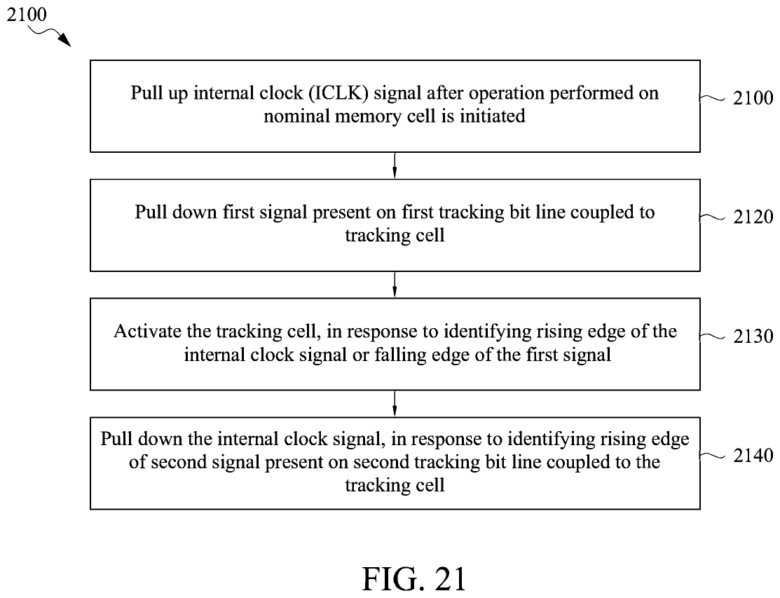

FIG. 21 illustrates a flow chart 2100 for operating a memory device including a memory controller configured to adjust the timing of a falling edge of an internal clock signal based on the voltage present on a TRKBL or a TRKBLB, in accordance with various embodiments. For example, at least some of the operations of the method 2100 can be performed by the controllers discussed with respect to FIGS. 1-9. Thus, in the following discussion of the methods 2100, the reference numerals used at least in FIGS. 1-9) may be reused. It is noted that the method 2100 is merely an example and is not intended to limit the present disclosure. Accordingly, it is understood that additional operations may be provided before, during, and after the method 2100 of FIG. 21, and that some other operations may only be briefly described herein.

The method 2100 may start with operation 2110 of pulling up an internal clock (ICLK) signal after an operation performed on a nominal memory cell is initiated. In some embodiments, a clock generator (e.g., 210 of FIG. 2, 310 of FIG. 3, 410 of FIG. 4, 510 of FIG. 5, 610 of FIG. 6, 710 of FIG. 7, 810 of FIG. 8, 910 of FIG. 9) can provide the ICLK signal with a rising edge, upon identifying the rising edge of a received clock (CLK) signal. Such a rising edge of the CLK signal is typically provided after an enable signal is asserted to perform a certain (e.g., write or read) operation on a nominal memory cell (e.g., 125).

The method 2100 may proceed to operation 2120 of pulling down a first signal present on a first tracking bit line coupled to a tracking cell. The TRKBL and TRKBL signal may be example implementations of the first tracking line and first signal, respectively. Prior to any operation, the TRKBL signal (or the TRKBL) may be pre-charged to VDD, or a logic 1, by a pre-charger (e.g., 220 of FIG. 2, 320 of FIG. 3, 420 of FIG. 4, 520 of FIG. 5, 620 of FIG. 6, 720 of FIG. 7, 820 of FIG. 8, 920 of FIG. 9). In some embodiments, upon the ICLK signal being pulled up, the pre-charger can stop charging the TRKBL, which causes the TRKBL signal to fall.

The method 2100 may proceed to operation 2130 of activating the tracking cell, in response to identifying a rising edge of the internal clock signal or a falling edge of the first signal. For example, when a TRKWL generator (e.g., 230 of FIG. 2, 430 of FIG. 4, 530 of FIG. 5, 630/640 of FIG. 6, 730/740 of FIG. 7) identifies a rising edge of the ICLK signal, the TRKWL generator can pull up a TRKWL signal which can in turn activate (e.g., turn on) one or more corresponding tracking cells. In another example, when a TRKWL generator (e.g., 330 of FIG. 3, 840 of FIG. 8, 940 of FIG. 9) identifies a falling edge of the TRKBL (first) signal, the TRKWL generator can pull up a TRKWL signal which can in turn activate (e.g., turn on) one or more corresponding tracking cells.

The method 2100 may proceed to operation 2140 of pulling down the internal clock signal, in response to identifying a rising edge of a second signal present on a second tracking bit line coupled to the tracking cell. The TRKBLB and TRKBLB signal may be example implementations of the second tracking line and second signal, respectively. In some embodiments, after the tracking cell(s) have been activated, the pre-charged TRKBL and the pre-discharged TRKBLB may start to fall and rise, respectively. The clock generator (e.g., 210 of FIG. 2, 310 of FIG. 3, 410 of FIG. 4, 510 of FIG. 5, 610 of FIG. 6, 710 of FIG. 7, 810 of FIG. 8, 910 of FIG. 9) can receive a trigger (TRIG) signal that closely follows the TRKBLB signal, and identify a rising edge of the TRIG signal to pull down the ICLK signal.

In one aspect of the present disclosure, a memory circuit is disclosed. The memory circuit includes a memory array comprising a plurality of first memory cells. The memory circuit includes a tracking column comprising one or more second memory cells, wherein each of the one or more second memory cells is coupled to a first tracking bit line, a second tracking bit line, and a first tracking word line. The memory circuit includes a controller operatively coupled to the memory array and the tracking column, and configured to: identify a transition edge of a first signal present on the first tracking bit line and assert a second signal present on the first tracking word line, causing a third signal present on the second tracking bit line to rise; and generate a trigger signal based on the third signal, wherein a transition edge of the trigger signal causes a write operation performed on at least one of the first memory cells to cease.

In another aspect of the present disclosure, a memory circuit is disclosed. The memory circuit includes a memory array comprising a plurality of first memory cells. The memory circuit includes a tracking column comprising one or more second memory cells, wherein each of the one or more second memory cells is coupled to a first tracking bit line, a second tracking bit line, and a first tracking word line, and configured to mimic a write operation performed on the first memory cells, wherein a first signal present on the first tracking bit line and a second signal present on the second tracking bit line have been provided at a logic 1 and a logic 0, respectively, prior to the write operation. The memory circuit includes a controller operatively coupled to the memory array and the tracking column, and configured to adjust a timing of a falling edge of an internal clock signal based on a rising edge of the second signal.

In yet another aspect of the present disclosure, a method for operating a memory circuit is disclosed. The method includes asserting an internal clock signal following initiation of a write operation performed on a nominal memory cell. The method includes negating a first signal present on a first tracking bit line coupled to a tracking cell. The method includes activating the tracking cell, in response to identifying a rising edge of the internal clock signal or a falling edge of the first signal. The method includes negating the internal clock signal, in response to identifying a rising edge of a second signal present on a second tracking bit line coupled to the tracking cell.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, +20%, or +30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory array comprising a plurality of first memory cells;
a tracking column comprising one or more second memory cells, wherein each of the one or more second memory cells is coupled to a first tracking bit line, a second tracking bit line, and a first tracking word line; and
a controller operatively coupled to the memory array and the tracking column, and configured to:
identify a transition edge of a first signal present on the first tracking bit line and assert a second signal present on the first tracking word line, causing a third signal present on the second tracking bit line to rise; and
generate a trigger signal based on the third signal, wherein a transition edge of the trigger signal causes a write operation performed on at least one of the first memory cells to cease.

2. The memory circuit of claim 1, wherein the controller is further configured to charge the first signal to a first logic state and discharge the third signal to a second logic state, respectively, prior to the write operation.

3. The memory circuit of claim 1, wherein the trigger signal substantially follows the third signal.

4. The memory circuit of claim 1, wherein the tracking column further includes one or more third memory cells, wherein each of the one or more third memory cells is coupled to the first tracking bit line, but not coupled to the second tracking bit line or the first tracking word line.

5. The memory circuit of claim 1, wherein the tracking column further includes one or more fourth memory cells, wherein each of the one or more fourth memory cells is coupled to the first tracking bit line and a second tracking word line, but not coupled to the second tracking bit line or the first tracking word line.

6. The memory circuit of claim 5, wherein the second signal present on the first tracking word line and a fourth signal present on the second tracking word line are logically inverse to each other.

7. The memory circuit of claim 6, wherein the controller includes a multiplexer controlled by an enable signal specifying either a read operation or the write operation to be performed on the at least one first memory cell, and the multiplexer has a first input and a second input coupled to the first tracking bit line and the second tracking bit line, respectively.

8. The memory circuit of claim 7, wherein the multiplexer is configured to select the third signal based on the enable signal specifying the write operation, and select the first signal based on the enable signal specifying the read operation.

9. The memory circuit of claim 1, wherein the controller includes a clock generator configured to provide an internal clock signal for the memory array.

10. The memory circuit of claim 9, wherein the transition edge of the trigger signal causes the internal clock signal to fall, which ceases the write operation or a read operation performed on the least one first memory cell.

11. A memory circuit, comprising:
a memory array comprising a plurality of first memory cells;
a tracking column comprising one or more second memory cells, wherein each of the one or more second memory cells is coupled to a first tracking bit line, a second tracking bit line, and a first tracking word line, and configured to mimic a write operation performed on the first memory cells, wherein a first signal present on the first tracking bit line and a second signal present on the second tracking bit line have been provided at a first logic state and a second logic state, respectively, prior to the write operation; and
a controller operatively coupled to the memory array and the tracking column, and configured to adjust a timing of a falling edge of an internal clock signal based on a rising edge of the second signal.

12. The memory circuit of claim 11, wherein the controller is further configured to provide a trigger signal substantially following the second signal.

13. The memory circuit of claim 12, wherein a rising edge of the trigger signal determines the timing of the falling edge of the internal clock signal.

14. The memory circuit of claim 11, wherein the controller is further configured to pull up a third signal present on the first tracking word line coupled to each of the one or more second memory cells, upon identifying a falling edge of the first signal.

15. The memory circuit of claim 11, wherein the tracking column further includes one or more third memory cells, wherein each of the one or more third memory cells is coupled to the first tracking bit line, but not coupled to the second tracking bit line or the first tracking word line.

16. The memory circuit of claim 11, wherein the tracking column further includes one or more fourth memory cells, wherein each of the one or more fourth memory cells is coupled to the first tracking bit line and a second tracking word line, but not coupled to the second tracking bit line or the first tracking word line.

17. The memory circuit of claim 16, wherein the controller is further configured to pull up, when the write operation is performed on the first memory cells, a third signal present on the first tracking word line, and pull up, when a read operation is performed on the first memory cells, a fourth signal present on the second tracking word line.

18. A method for operating a memory circuit, comprising:
asserting an internal clock signal following initiation of a write operation performed on a nominal memory cell;
negating a first signal present on a first tracking bit line coupled to a tracking cell;
activating the tracking cell, in response to identifying a rising edge of the internal clock signal or a falling edge of the first signal; and
negating the internal clock signal, in response to identifying a rising edge of a second signal present on a second tracking bit line coupled to the tracking cell.

19. The method of claim 18, further comprising generating a trigger signal substantially follows the second signal, wherein a rising edge of the trigger signal causes the negation of the internal clock signal.

20. The method of claim 18, wherein, prior to the write operation, the first signal has been pre-charged to a first logic state and the second signal has been pre-discharged to a second logic state.
